(19) United States
(12) Patent Application Publication
(10) Pub. No.: US 2005/0048706 A1
(43) Pub. Date: Mar. 3, 2005

(54) Method of manufacturing semiconductor device

(75) Inventors: Akihisa Shimomura, Kanagawa (JP); Takashi Hamada, Kanagawa (JP)

Correspondence Address: NIXON PEABODY, LLP, 401 9TH STREET, NW, SUITE 900, WASHINGTON, DC, 20004-2128, US

(73) Assignee: Semiconductor Energy Laboratory Co., Ltd., Kanagawa-ken (JP)

(21) Appl. No.: 10/914,199

(22) Filed: Aug. 10, 2004

(30) Foreign Application Priority Data
Aug. 27, 2003 (JP) 2003-303442

(51) Int. Cl. H01L 21/336

(52) U.S. Cl. 438/197

(57) ABSTRACT

To irradiate a laser beam with the use of a mask having a different material and structure from the conventional one in the case where wide-ranging output laser beam is selectively irradiated. One feature of the present invention is that the laser beam is selectively irradiated by using a mask for reflecting the laser beam. The mask is formed of laminated films composed by laminating at least a first material and a second material. When the refractive index of the first material is n1; the refractive index of the second material is n2; and the refractive indices satisfy n1<n2, an amorphous semiconductor film, the first material, and the second material are sequentially laminated over a substrate to irradiate from a side of a top surface of the substrate with the laser beam.

### BACKGROUND OF THE INVENTION

1. Field of the Invention

The present invention relates to a method of manufacturing a semiconductor device including a crystalline semiconductor film and an amorphous semiconductor film.

2. Description of the Related Art

As for the conventional laser irradiation method, there is a method for selective irradiation with laser beam with use of a mask or a metal mask by photolithography (see patent document 1). According to the laser irradiation method as disclosed in the patent document 1, a silicon film formed in a source driver and a gate driver is necessary to be crystallized by irradiation with the laser beam, and the source driver and the gate driver are irradiated with the laser beam while an active matrix circuit is covered with a mask.

Further, there is another conventional method for forming a thin film semiconductor device as follows. After forming an amorphous semiconductor film, a protective film, which can transmit a laser beam, is formed thereon. After crystallizing the amorphous semiconductor film by irradiation with the laser beam, the protective film is removed therefrom such that the surface of the semiconductor film is exposed, and then a coating film, which serves as a gate insulating film, is formed thereon (see patent document 2). As disclosed in the patent document 2, a planar TFT in which the crystallinity of a silicon film is improved by irradiation with KrF excimer laser beam, is formed in a peripheral circuit portion whereas an inverted-stagger TFT is formed as an amorphous silicon (a-Si) TFT in an active matrix region (see embodiment 1 of the patent document 2). Furthermore, the laser beam is irradiated only to the peripheral circuit portion while the active matrix region is covered with a photoresist etc. (see embodiment 4 of the patent document 2).

[Patent Document 1]

Japanese Patent Application Laid-Open No. Hei 8-125192
   [Patent Document 2]
Japanese Patent Application Laid-Open No. Hei 6-89905 (FIG. 1, and FIG. 7)

Since the mask is formed of the photoresist, however, the semiconductor film is likely to be contaminated with impurities from the resist mask.

Also, since the output power of a laser beam oscillated from a resonator has been developed recently, there is concern that the conventional mask material as disclosed in the above-mentioned patent documents cannot withstand the high power laser beam because of its lower-level resistance against the laser beam. Specifically, when laser beam is selectively irradiated with use of a resist mask or a metal mask, the mask is likely to be expanded, which results in misalignment of the mask. Further, when the resist mask or the meal mask cannot withstand against the high power laser beam anymore, the mask is likely to be damaged.

### SUMMARY OF THE INVENTION

It is an object of the invention to provide a method of selective irradiation with a laser beam with wide-ranging output power by using a material and structure, which are different from those of the above-mentioned patent documents.

In view of the foregoing, one feature of the invention is that a mask reflecting the laser beam is provided to irradiate with the laser beam selectively. Consequently, an amorphous semiconductor film is selectively crystallized, and partly becomes a crystalline semiconductor film.

In the present invention, the laser beam may be irradiated either from a side of a top surface of a substrate with a semiconductor film formed thereon, or from a side of a back surface of the substrate.

More specifically, a crystalline semiconductor film, which is selectively irradiated with the laser beam, may be used as a thin film transistor in a driving circuit portion comprising a signal line driving circuit or a scanning line driving circuit. Meanwhile, a semiconductor film, which is not irradiated with the laser beam, i.e., an amorphous semiconductor film, may be used as a thin film transistor in a pixel portion. As compared with the case of using a polycrystalline semiconductor film, when the amorphous semiconductor film is used for the thin film transistor in the pixel portion, variation between adjacent thin film transistors is reduced. Besides, the variation in electric characteristics; more specifically, the variation in threshold voltage (Vth) of the thin film transistor formed of the amorphous semiconductor film is also reduced. Of course, the amorphous semiconductor film can overcome the variation in crystallinity caused by uneven irradiation of the laser beam due to the fluctuation of laser power. As a result, nonuniform display of the display device can be suppressed.

According to the invention, the semiconductor film formed over the substrate, which is the amorphous semiconductor film, may be composed of any one of an amorphous semiconductor film; a semiamorphous semiconductor (hereinafter, referred to as SAS) in which crystal grains are dispersed among an amorphous semiconductor; and a microcrystalline semiconductor in which 0.5 nm to 20 nm of crystal grains are dispersed in an amorphous semiconductor. The fine crystals having 0.5 nm to 20 nm of crystal grains are also referred to as microcrystals (μc).

As a material for the above-mentioned amorphous semiconductor film, silicon (Si), silicon-germanium (SiGe), and silicon carbide (SiC) can be used. The amorphous semiconductor film sometimes includes hydrogen besides the foregoing substances, and is generally denoted by a-Si:H, a-SiGe:H, or a-SiC:H.

The SAS can be formed by diluting SiH₄ with H₂ using plasma CVD, and has an intermediate structure between an amorphous structure and a crystalline structure (including a single crystal and a polycrystal). The semiconductor having the intermediate structure has a third condition that is stable in terms of free energy, and is a crystalline semiconductor having short range order and lattice distortion. Further, the SAS contains oxygen at a concentration of 5×10¹⁹ atom/cm³ or less, and includes a Raman peak at wavenumbers lower than 520 cm⁻¹ according to the measurement of Raman spectrum.

The SAS also includes hydrogen or halogen of at least 1 atomic % or more as a neutralizing agent of dangling bonds. Further, a rare gas element such as helium, argon, krypton, and neon is additionally added into the SAS to promote the lattice distortion, thereby obtaining a stable and favorable SAS. For example, such SAS is disclosed in Japanese Patent No. 3,065,528.

A mask is formed of laminated films (composed by layering two or more films) of at least a first material (film) and a second material (film). When the refractive index of the first material is set to n1, the refractive index of the second material is set to n2, and the indices satisfies n1<n2, it is preferable that the first material and the second material be sequentially laminated over the amorphous semiconductor film such that the second material is nearest to the laser beam. That is, when the laser beam is irradiated from a side of a top surface of the substrate, the amorphous semiconductor film, the first material, and the second material are laminated in order over the substrate. On the other hand, when the laser beam is irradiated from under the amorphous semiconductor film, i.e., the laser beam is irradiated from a side of a back surface of the substrate, the first material and the second material are laminated in order over the back surface of the substrate.

Further, one feature of the invention is that each of the first and second materials constituting the mask has 0.01 or less of the extinction coefficient (k) with respect to the wavelength of irradiation with the laser beam.

The first material and the second material for constituting the mask may be laminated in plural times, alternately. By laminating the first and second materials alternately, the reflectance of the laser beam can be further enhanced.

In the case where the refractive index of the first material is n1, the refractive index of the second material is n2, and the wavelength of the laser beam irradiating the amorphous semiconductor film is λ, it is preferable that the film thickness of the first material satisfy (λ/4)×n1, and the film thickness of the second material satisfy (λ/4)×n2.

Concretely, a silicon oxynitride (SiON) film can be used for the first material, and a silicon nitride oxide (SiNO) film can be used for the second material. Namely, the laser beam can be selectively irradiated with use of a mask, which is composed by laminating the silicon oxynitride (SiON) film and the silicon nitride oxide (SiNO) film. In the invention, the silicon oxynitride film indicates a film including more oxygen content than nitrogen content with respect to the composition ratio, wherein silicon oxide is nitrided. Meanwhile, the silicon nitride oxide film indicates a film including more nitrogen content than oxygen content with respect to the composition ratio, wherein silicon nitride is oxidized.

The silicon oxynitride (SiON) film and the silicon nitride oxide (SiNO) film can be continuously formed in the same chamber by controlling the flow rate of material gas. Since the silicon oxynitride (SiON) film and the silicon nitride oxide (SiNO) film can be formed by CVD with superior distribution of the film thickness, these films are favorable. More specifically, the silicon oxynitride (SiON) film and the silicon nitride oxide (SiNO) film can be formed by such methods as CVD; plasma CVD; reduced pressure CVD (LPCVD); RF plasma CVD; microwave CVD; and electron cyclotron resonance (ECR) CVD. Note that the methods for forming the silicon oxynitride (SiON) film and the silicon nitride oxide (SiNO) film are not limited thereto, and the films may be formed by sputtering, vapor deposition etc.

When only either the first material or the second material constituting the laminated films is formed, the absorptance of the laser beam can be improved. That is, either the first material or the second material of the laminated films is selectively formed over a region to be irradiated with the laser beam, and hence, the laser beam can be efficiently absorbed by the material. In particular, when the laser beam is irradiated from a side of the back surface of the substrate, selectively, either the first material or the second material is preferably formed in the region to be irradiated with the laser beam on the back surface of the substrate. In the case of irradiating with the laser beam from a side of the back surface of the substrate, there is concern that the laser beam intensity is attenuated by the substrate. By forming the first material or the second material over the back surface of the substrate, the absorptance of the laser beam is preferably increased.

In the invention, as for the laser beam irradiating the amorphous semiconductor film, a pulsed laser beam or a continuous wave laser beam (hereinafter referred to as a CW laser beam) can be used.

As for the pulsed laser beam or the CW laser beam, for example, a gas laser, a solid-state laser, and a metal laser can be employed. Specifically, one or more of the following lasers can be used: an Ar laser; a Kr laser; an excimer laser; a YAG laser; a Y₂O₃ laser; a YVO₄ laser; a YLF laser; a YAlO₃ laser; a glass laser; a ruby laser; an alexandrite laser; a Ti:sapphire laser; a copper steam laser; and a gold steam laser. Furthermore, the fundamental waves may be converted into the higher harmonics such as the second harmonics and the third harmonics by using a nonlinear optical element.

In the present invention, the amorphous semiconductor film may be selectively added with a metal element for promoting crystallization (hereinafter simply referred to as a metal element) prior to irradiating with the laser beam. As a mask for selectively adding the metal element, the mask for selective irradiation with the laser beam according to the present invention can be employed. The metal element may be selected from one or more of Ni, Fe, Co, Pd, Pt, Cu, Au, Ag, In, and Sn. Further, the amorphous semiconductor film may be selectively crystallized by performing a heat treatment using an electric furnace to form a crystalline semiconductor film, selectively. The metal element may be doped into the amorphous semiconductor film so as to promote the crystallization of the amorphous semiconductor film. For instance, the metal element can be added into the amorphous semiconductor film by a method for applying a solution containing the metal element such as spin coating and dipping; ion implantation; or sputtering.

According to the invention, by laminating different materials such as the silicon oxynitride film and the silicon nitride oxide film, the total thickness of the mask can be reduced. Meanwhile, when the mask is composed of a single-layered silicon oxynitride film or a single-layered silicon nitride oxide film, the thickness of the mask must be several hundreds μm in order to reflect the laser beam with the mask, efficiently. Such thick mask with several hundreds μm in thickness exhibits unstable properties. When the thick mask is formed over the substrate, a yield of manufacturing steps is reduced; and therefore, the thick mask is not suitable for mass-production.

According to the invention, by laminating the first material (n1) having the lower refractive index and the second material (n2) having the higher refractive index than that of the first material in order as the mask, the laser beam can be efficiently reflected with the mask. Consequently, the resistance against the laser beam of the mask can be improved, and hence, the amorphous semiconductor film can be selectively crystallized, extensively. As a result, the laser crystallization can be selectively carried out so as to make the crystallinities of the semiconductor film in the pixel portion and the driver circuit portion difference according to the invention.

As compared with the case of irradiating with the laser beam while controlling the irradiation position of the laser beam without using the mask, when the laser beam is selectively irradiated with use of the mask according to the invention, alignment accuracy of the margin between a region irradiated with the laser beam and a region not irradiated with the laser beam is improved. In particular, when a plurality of panels are manufactured from a large-size substrate; i.e., multiple panels are divided from the large-size substrate, it is preferable that the laser beam be selectively irradiated with use of the mask according to the present invention.

Further, as compared with the case of using a polycrystalline semiconductor film, when the amorphous semiconductor film is used for a thin film transistor of the pixel portion, the variation between adjacent thin film transistors is reduced. In addition, the variation in electric characteristics, particularly, in threshold voltages (Vth) of the thin film transistor comprising the amorphous semiconductor film can also be reduced. Furthermore, by changing the semiconductor film in the pixel portion into an amorphous state, a microcrystalline state, and a semiamorphous state, the variation in crystallinity caused by uneven irradiation of the laser beam due to output power fluctuation of the laser beam can be overcame. As a result, nonuniform display of the display device can be improved, thereby increasing a display quality.

Further, when the crystalline semiconductor film is used for a thin film transistor of the driver circuit portion, a narrower frame formation can be realized.

### BRIEF DESCRIPTION OF THE DRAWINGS

FIGS. 1A and 1B are diagrams showing a step for irradiating with a laser beam with use of a mask according to the invention;

FIGS. 2A and 2B are diagrams showing a step for irradiating with a laser beam with use of a mask according to the invention;

FIGS. 3A to 3D are diagrams showing a step for manufacturing a thin film transistor according to the invention;

FIGS. 4A and 4B are diagrams showing a step for manufacturing a thin film transistor according to the invention;

FIG. 5 is a diagram showing a step for manufacturing a thin film transistor according to the invention;

FIGS. 6A to 6D are diagrams showing a step for manufacturing a thin film transistor according to the invention;

FIGS. 7A and 7B are diagrams showing a step for manufacturing a thin film transistor according to the invention;

FIGS. 8A and 8B are diagrams showing a step for manufacturing a thin film transistor according to the invention;

FIGS. 9A and 9B are diagrams showing a step for manufacturing a thin film transistor according to the invention;

FIGS. 10A to 10C are diagrams showing electronic appliances comprising a thin film transistor according to the invention;

FIGS. 11A to 11C are graphs showing light transmittances, reflectances, and absorptances depending on the presence or absence of a mask, respectively;

FIGS. 12A and 12B are graphs showing absorptances depending on the difference in structure of laminated films as a mask according to the invention;

FIG. 13A is a diagram showing a structure of a mask and FIG. 13B is a Raman spectrum showing crystallized states in a region where the mask is formed or a region where the mask is not formed;

FIGS. 14A and 14B are diagrams showing a step for forming multiple panels with use of a mask according to the invention;

FIG. 15 is a diagram showing a module manufactured with use of a mask according to the invention; and

FIGS. 16A to 16C are diagrams showing a structure of a display device according to the invention.

### DETAILED DESCRIPTION OF THE INVENTION

[Embodiment Mode 1]

In Embodiment Mode 1, a structure of a mask formed over an amorphous semiconductor film will be described.

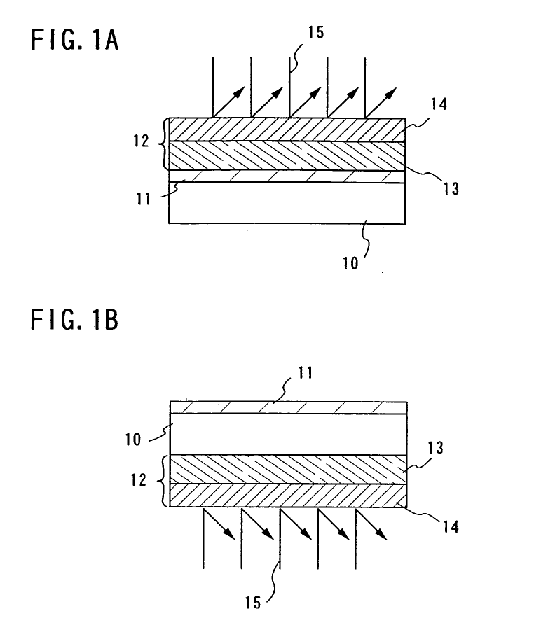

In FIG. 1A, a mask 12 is formed over a top surface of a substrate 10 having an insulated surface while interposing an amorphous semiconductor film 11 therebetween. The mask 12 is composed of a first material 13 and a second material 14. It is preferable that the first material be formed of a material having lower refractive index, and the second material be formed of a material having higher refractive index than that of the first material. For example, the first material 13 may be formed of a silicon oxynitride (SiON) film, whereas the second material 14 may be formed of a silicon nitride oxide (SiNO) film. Further, for instance, the silicon oxynitride (SiON) film may be formed by plasma-CVD under a condition in which SiH₄ and N₂O are used as material gases; the pressure is 0.3 Torr; RF power is 150 W; RF frequency is 60 MHz; and the substrate temperature is 400° C. The silicon nitride oxide (SiNO) film may be formed by plasma-CVD under a condition in which SiH₄, N₂O, NH₃, and H₂ are used as material gases; the pressure is 0.3 Torr; RF power is 50 W; RF frequency is 60 MHz; and the substrate temperature is 400° C.

The film thickness of the silicon oxynitride (SiON) film and the film thickness of the silicon nitride oxide (SiNO) film can be determined depending on the wavelength of the irradiation with a laser beam and refractive indices of each material. More specifically, in case of using a laser beam with a wavelength of 308 nm, each film thickness can be determined according to experimental results in Embodiment 1.

When a laser beam 15 is irradiated from a side of the top surface of the substrate while covering the amorphous semiconductor film 11 with the mask 12, the laser beam 15 is reflected by the mask 12, and energy of the laser beam irradiating to the amorphous semiconductor film 11 is reduced. Therefore, the amorphous semiconductor film 11 is not crystallized, or the amorphous semiconductor film is slightly crystallized. As compared with a region with no mask formed thereon, the amorphous semiconductor film with the mask formed thereon becomes a semiconductor film having lower crystallinity. When the silicon oxynitride (SiON) film and the silicon nitride oxide (SiNO) film used for the mask 12 are necessary to be etched selectively, these films may be removed by wet etching using etchant, which includes phosphoric acid.

Unlike in the case of FIG. 1A, FIG. 1B shows the case in which the laser beam is irradiated from a side of a back surface of the substrate.

In FIG. 1B, the amorphous semiconductor film 11 is formed over the top surface of the substrate 10 having the insulated surface, whereas the mask 12 is formed over the back surface of the substrate 10. The mask 12 comprises the same structure as that in FIG. 1A. It is preferable that the first material be formed of a material having lower refractive index, and the second material be formed of a material having higher refractive index than that of the first material. That is, the material having the higher refractive index is preferably formed on an outer surface to be irradiated with the laser beam directly, and the material having lower refractive index is formed under the material having higher refractive index toward a substance to be irradiated, i.e., toward the amorphous semiconductor film 11.

When the laser beam 15 is irradiated from a side of the back surface of the substrate while covering the back surface of the substrate with the mask 12, the laser beam 15 is reflected by the mask 12, and therefore the energy of the laser beam irradiating to the amorphous semiconductor film 11 is reduced. Accordingly, the amorphous semiconductor film 11 is not crystallized completely, and remains to be slightly crystallized. The amorphous semiconductor film becomes a semiconductor film having lower crystallinity than that of the region with no mask formed thereon.

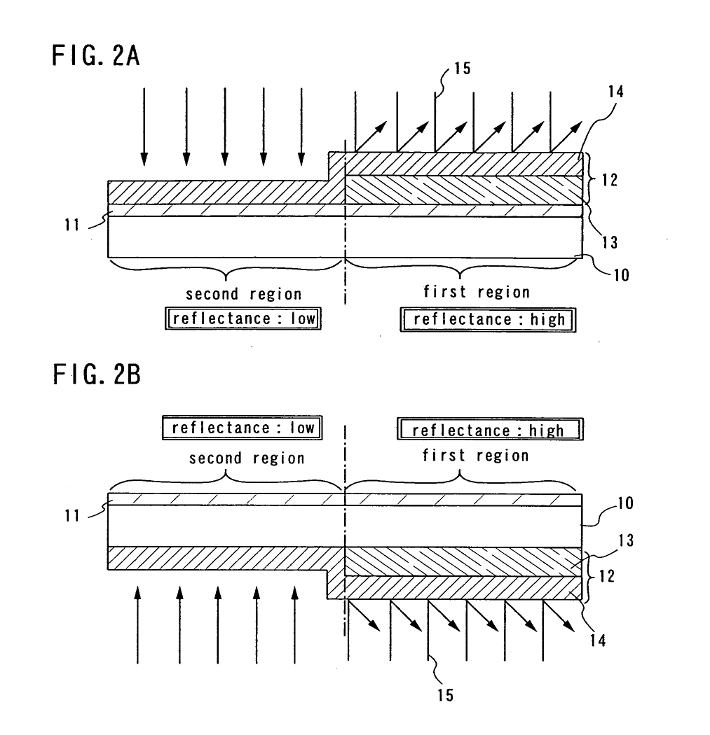

Unlike in the case of FIGS. 1A and 1B, FIG. 2A shows a structure in which on the amorphous semiconductor film 11 formed on the top surface of the substrate 10 including the insulated surface, laminated films composed of the first material and the second material are formed as a mask in a first region and a single-layered film composed of the second material is formed as a mask in a second region. According to the structure, the reflectance of the laser beam 15 can be enhanced in the first region covered with the laminated films formed thereon, whereas the absorptance of the laser beam 15 can be improved in the second region covered with the single-layered film.

For example, a silicon oxynitride (SiON) film can be used for the first material 13, and a silicon nitride oxide (SiON) film can be used for the second material 14. Each film thickness of the silicon oxynitride (SiON) film and the silicon nitride oxide (SiNO) film can be determined in accordance with the wavelength of the laser beam to be irradiated and each refractive index of the materials. Specifically, in the case where the laser beam wavelength is 308 nm, the film thickness for improving the reflectance of the laser beam in the first region and the film thickness for enhancing the absorptance of the laser beam in the second region can be determined according to experimental results of Embodiment 1 etc.

Further, unlike in the case of FIG. 2A, FIG. 2B shows the case of irradiating with a laser beam from a side of the back surface of the substrate.

FIG. 2B shows a structure comprising the amorphous semiconductor film 11 formed over the top surface of the substrate 10 with an insulated surface; and masks 12 formed on the back surface of the substrate 10. The laminated films composed of the first material and the second material are formed as a mask in the first region, and a single-layered film composed of the second material is provided as a mask in the second region. The laser beam 15 is irradiated from a side of the back surface of the substrate.

When the laser beam 15 is irradiated from a side of the back surface of the substrate, there is concern that energy of the laser beam 15 is attenuated with the substrate 10. Therefore, as shown in FIG. 2B, it is preferable that a mask for decreasing the reflectance of the laser beam 15, i.e., an antireflection film be formed in the second region.

Although the mask 12 is provided on the back surface of the substrate in FIG. 2B, it is also possible that the mask 12 is formed on the top surface of the substrate 10, the amorphous semiconductor film 11 is formed over the mask, and the laser beam 15 is irradiated from a side of the back surface of the substrate. In such case, the mask 12 for improving the energy absorptance of the laser beam 15 and the amorphous semiconductor film 11 are arranged extremely close to each other, thereby exhibiting significant advantageous effects.

Since the above-mentioned masks are not expanded or damaged with the laser beam energy by reflecting the laser beam, the mask of the present embodiment mode is preferable. In addition, the laser beam can be selectively irradiated with use of the mask of the present embodiment mode, and therefore, the embodiment mode is preferable in the case where multiple panels are manufactured from one substrate.

Furthermore, since the reflectance of the laser beam can be improved or reduced with the mask 12, the mask according to the embodiment mode is preferably used in a step for selective irradiation with the laser beam.

[Embodiment Mode 2]

Embodiment Mode 2 will describe steps for manufacturing a thin film transistor including a laser crystallization step with use of a mask, and steps for manufacturing a display device including a light emitting element typified by an organic light emitting element for each pixel.

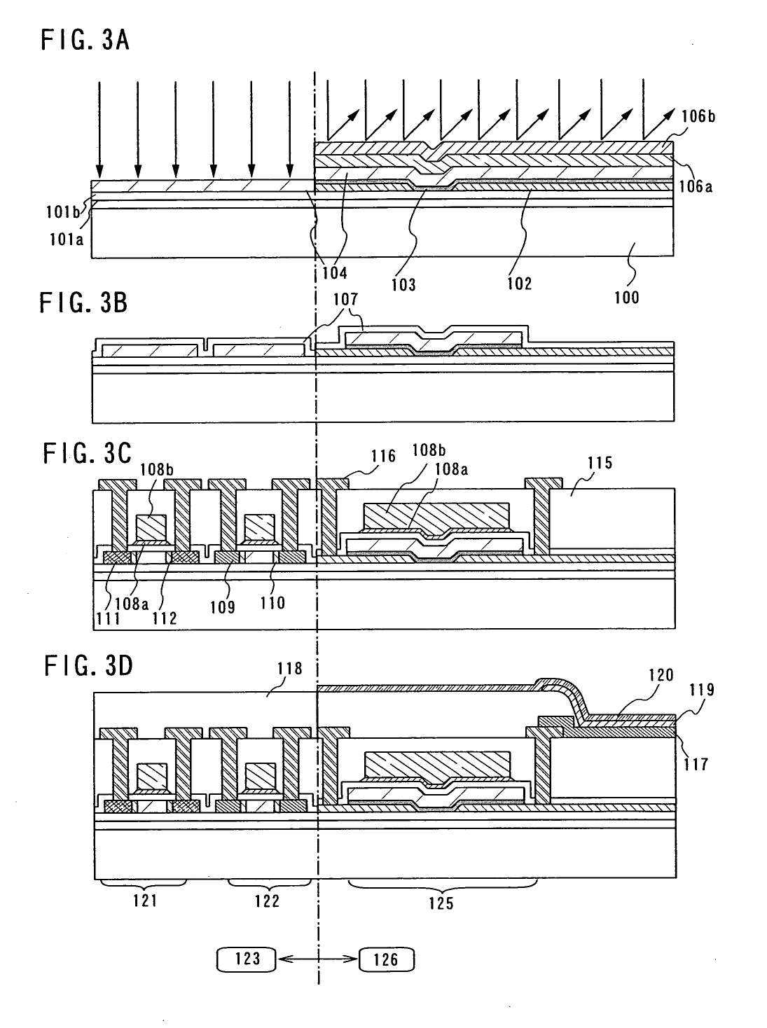

Firstly, as illustrated in FIG. 3A, base films including laminated films 101a and 101b are formed over a top surface of a substrate 100 having an insulated surface. As the substrate 100, for example, a glass substrate such as a barium-borosilicate glass and an alumino-borosilicate glass, a quartz substrate, an SUS substrate and the like can be used. In addition, although a substrate formed of flexible synthetic resin such as acryl and plastic typified by PET, PES, and PEN generally tends to be inferior in heat resistance as compared with the other substrates, the substrate made of flexible synthetic resin can be used when it can withstand the processing temperature in the manufacturing steps.

The base films 101 are provided in order to prevent alkaline-earth metal or alkali metal such as Na included in the substrate 100 from dispersing into the semiconductor film to have an adverse effect on the characteristics of the semiconductor element. Therefore, the base films are formed of an insulating film such as silicon oxide, silicon nitride, and silicon nitride oxide, which can prevent the dispersion of the alkaline-earth metal and alkali metal into the semiconductor film. In the present embodiment mode, a silicon oxynitride film is formed in a thickness from 10 to 200 nm (preferably from 50 to 100 nm) and a silicon nitride oxide film is formed thereon in a thickness from 50 to 200 nm (preferably from 100 to 150 nm) by plasma-CVD. Note that a single-layered film maybe used as substitute for the laminated base films. For example, the silicon nitride oxide film is formed in a thickness from 10 to 400 nm (preferably, in a thickness from 50 to 300 nm).

In the case of using the substrate including trace amounts of the alkali metal or the alkaline-earth metal such as the glass substrate, the SUS substrate, and the plastic substrate, it is effective to provide the base films in consideration of preventing the dispersion of impurities. However, when the dispersion of the impurities does not lead to any significant problems, for example in the case of using the quartz substrate, the base films are not always necessary to be provided.

A semiconductor film 102 having one conductivity type is formed on the base films 101 in the pixel portion and then patterned so as to serve as a source electrode or a drain electrode. A semiconductor film 103 having N-type conductivity is further formed thereon. At this moment, a resist mask may be formed in a driver circuit portion.

Next, an amorphous semiconductor film 104 is formed in a pixel portion, and the driver circuit portion. At this moment, the resist mask formed in the driver circuit portion may be removed prior to forming the amorphous semiconductor film 104. The film thickness of the amorphous semiconductor film 104 is set to from 25 to 100 nm (preferably, from 30 to 60 nm). The amorphous semiconductor film can be formed of a material including silicon germanium, besides a silicon-based material. In the case of using the material including silicon germanium, it is preferable that the concentration of the germanium be set to about 0.01 to 4.5 atomic %. insulating film including silicon to a thickness of from 10 to 150 nm. In the case of a submicron-sized TFT having an extremely small channel formation region, the gate insulating film is preferably formed of the insulating film including silicon with a thickness of from 10 to 50 nm. In the embodiment mode, the gate insulating film 107 is formed of a silicon oxynitride film (composition ratio: Si=32%, O=59%, N=7%, and H=2%) with a thickness of 30 nm by plasma-CVD. Of course, the gate insulating film is not particularly limited to the silicon oxynitride film, and the other insulating film including silicon with a single-layered or a lamination-layered structure may be used.

As depicted in FIG. 3C, conductive films 108, which will serve as gate electrodes, are formed over the amorphous semiconductor film and the crystalline semiconductor film while interposing the gate insulating film 107 therebetween. The conductive films 108 may be formed of an element selected from Ta, W, Ti, Mo, Al, and Cu, or an alloy material or compound material containing the above-mentioned elements as its principal constituent. The conductive films may be either a single-layered or a lamination-layered. In the embodiment mode, 50-nm-thick tantalum nitride films as first conductive films 108a, and 370-nm-thick tungsten films as second conductive films 108b are subsequently formed and laminated so as to cover the gate insulating film 107. The first conductive films 108a and the second conductive films 108b are etched with use of a resist mask. The etching conditions of the embodiment mode are as follows: each edge of the first conductive films 108a are tapered, and the second conducive films 108b are made narrower than the first conductive films.

Note that, when the conductive films are etched, if the etching conditions for the pixel portion differ from those for the driver circuit portion, either the pixel portion or the driver circuit portion may be etched while covering another portion with a resist mask.

As illustrated in the embodiment mode, an impurity element is added in a self-aligning manner with use of the gate electrodes so as to form impurity regions 109 and 111. At this moment, an n-channel impurity region 109 is formed by doping an impurity element such as boron (B), whereas a p-channel impurity region 111 is formed by doping an impurity element such as phosphorous (P). Further, n-channel low concentration impurity regions (i.e. GOLD regions) 110 and p-channel low concentration impurity regions 112 are formed underneath the tapered portions of the first conductive films 108a.

When a SAS (semiamorphous semiconductor) is used as the amorphous semiconductor film 104, the SAS can be obtained by decomposing silicon gas by glow discharging. As for the silicon gas, SiH₄ can be typically used, as well as Si₂H₆, SiH₂Cl₂, SiHCl₃, SiCl₄, SiF₄ and the like. The SAS can be easily formed by diluting the silicon gas with hydrogen or hydrogen and one or more rare gas elements selected from helium, argon, krypton, and neon. In the embodiment mode, the 40-nm-thick amorphous semiconductor film (also referred to as an amorphous silicon film) including silicon as its principal constituent is formed by plasma-CVD.

Subsequently, laminated films 106a and 106b are formed as a mask over the amorphous semiconductor film 104 provided in the pixel portion. In the embodiment mode, the first material 106a constituting the laminated films is formed of a silicon oxynitride (SiON) film and the second material 106b is formed of a silicon nitride oxide (SiNO) film. Each film thickness of the silicon oxynitride (SiON) film and the silicon nitride oxide (SiNO) film can be determined according to Embodiment 1. In the embodiment mode, the film thickness of the silicon oxynitride (SiON) film is set to 45 nm, and the film thickness of the silicon nitride oxide (SiNO) film is set to 40 nm.

When the top surface of the substrate is irradiated with pulsed excimer laser beam (XeCl: wavelength of 308 nm), about 70% of the laser beam irradiating the amorphous semiconductor film 104 in the pixel portion is reflected with the mask. Accordingly, the crystallinity of the amorphous semiconductor film 104 formed in the pixel portion is not enhanced, and the amorphous semiconductor film still remains in its amorphous state. On the other hand, the amorphous semiconductor film 104 formed in the driver circuit portion is crystallized to become a crystalline semiconductor film.

As illustrated in FIG. 3B, the semiconductor film 103 having the N-type conductivity formed in the pixel portion, the amorphous semiconductor film 104 also formed in the pixel portion, and the crystalline semiconductor film formed in the driver circuit portion are patterned, respectively. At this moment, in consideration of the electric characteristics of the thin film transistor, it is preferable that a channel formation region be patterned as large as possible from the amorphous semiconductor film, which remains in its amorphous state.

Thereafter, a gate insulating film 107 is formed to cover the amorphous semiconductor film and the crystalline semiconductor film. The gate insulating film 107 is formed of an

After forming an insulating film made from a silicon nitride film etc. for covering the gate electrodes, the substrate is heated at a temperature of from about 400 to 450° C. so as to carry out dehydrogenation of the semiconductor film. Subsequently, an interlayer insulating film 115 is formed. The interlayer insulating film 115 may be formed of an insulating film including an inorganic material or an organic material. Alternatively, the interlayer insulating film 115 may be formed of a material having a skeleton group with a bond of silicon and oxygen and including hydrogen or alkyl group, i.e., siloxane. In the embodiment mode, the interlayer insulating film is formed of an insulating film including silicon oxide to a thickness of 1.05 μm.

Preferably, a plurality of interlayer insulating films 115 may be laminated. In the case where wirings 116 and the other plurality of wirings are formed at the same layer, openings for providing an electroluminescent layer can be widely formed by laminating the plurality of interlayer insulating films 115.

The wirings (also referred to as source wirings or drain wirings) 116 are formed so as to be connected to the impurity regions 109 and 111 formed in the source electrode, the drain electrode and the driver circuit portion, which are formed in the pixel portion. Signal lines and power source lines are formed in the pixel portion simultaneously with the wirings 116. A film including an element selected from aluminum (Al), titanium (Ti), molybdenum (Mo), tungsten (W), and silicon (Si), or an alloy film including these elements may be used as the wirings 116. Or, the wirings may be formed by nitriding these metal elements. In this embodiment mode, after laminating a 100-nm-thick titanium film, a 350-nm-thick titanium-aluminum alloy film, and a 100-nm-thick titanium film (Ti/Al—Si/Ti), respectively, the laminated layers are patterned and etched into desired shapes.

As illustrated in FIG. 3D, the amorphous semiconductor film, which is an n-channel TFT 125 including an amorphous silicon (a-Si) film in this embodiment mode, is formed in the pixel portion 126. Meanwhile, the crystalline semiconductor films, which are an n-channel TFT 122 and a p-channel TFT 121 including a crystalline silicon (p-Si) film, are formed in the driver circuit portion 123. The present embodiment mode employs a top-gate structure in which the n-channel TFT 125 formed in the pixel portion and the n-channel TFT 122 and the p-channel TFT 121 formed in the driver circuit portion are provided at an upper portion of a semiconductor film, i.e., gate electrodes are formed at an upper portion of the channel formation region. However, a bottom-gate structure, in which above-mentioned gate electrodes are formed at a lower portion of the channel formation region, may also be employed.

A first electrode (anode or cathode) 117 of a light emitting element, which is formed in the pixel portion, is formed so as to be contacted to any one of the electrode of TFTs including the crystalline semiconductor film. In the embodiment mode, a cathode of the light emitting element is formed so as to be contacted to the drain electrode of the n-channel TFT 125.

An insulating film 118 is formed so as to cover the wirings 116 and edges of the first electrode (anode or cathode) 117 of the light emitting element. The insulating film 118 is formed by a light emitting material arranged in matrix and serves as a partition wall, namely, a bank. The insulating film 118 is formed of an inorganic material, or a photosensitive or nonphotosensitive organic material. When the insulating film 118 is formed of a negative type photosensitive acrylic, for example, a bank is formed at the edge of the insulating film 118, wherein the upper edge of the insulating film 118 is curved to have a first curvature radius, and the lower edge of the insulating film 118 is curved to have a second curvature radius. It is preferable that the first curvature radius and the second curvature radius be in the range of from 0.2 μm to 3.0 μm. In the case where the insulating film 118 is formed of the organic material, a silicon nitride film is preferably formed as a passivation film.

Thereafter, an opening is formed at the bank above the first electrode 117 of the light emitting element. The edges of the opening, especially, the lower edges thereof are preferably formed so as to have smooth tapered shapes. In the opening, an extremely thin electroluminescent layer 119 is formed and a second electrode 120 of the light emitting element is formed thereon. By interposing the electroluminescent layer 119 between the first and second electrodes, it is possible to prevent the first electrode 117 of the light emitting element from being shorted to the second electrode 120 of the light emitting element.

The first electrode and the second electrode of the light emitting element may serve as either an anode or a cathode depending on a pixel structure. For example, specific materials for the electrodes in the case where the first electrode serves as an anode and the second electrode serves as a cathode will be described as follows.

It is favorable to use metal, alloy, electric conductive compound, and a mixture thereof having high work function (work function is 4.0 eV or more) as the anode material. More specifically, the anode material may be ITO (indium tin oxide); IZO (indium zinc oxide) including indium oxide which is mixed with 2 to 20% zinc oxide (ZnO); gold (Au); platinum (Pt); nickel (Ni); tungsten (W); chromium (Cr); molybdenum (Mo); iron (Fe); cobalt (Co); copper (Cu); palladium (Pd); a metal nitride material such as titanium nitride (TiN), etc.

On the other hand, it is preferable to use metal, alloy, electric conductive compound, and a mixture thereof having low work function (work function is 3.8 eV or less) as the cathode material. Specifically, the cathode can be formed of such materials as elements belonging to Group 1 or Group 2 of the periodic table. That is, alkali metal such as Li and Cs; alkaline-earth metal such as Mg, Ca and Sr; alloy including these elements (such as Mg:Ag and Al:Li); chemical compound including these elements (such as LiF, CsF, and CaF₂); and transition metal including rare-earth metal can be used as the cathode material. Note that, since the cathode needs to have light transmitting properties, the cathode is formed by laminating the above-mentioned metal or alloy including the above-mentioned metals, which is formed with an extremely thin thicknesses, and a metal such as ITO (including alloy). The anode and cathode can be formed by vapor deposition, sputtering, and the like.

In addition, when the full-color display is performed, the electroluminescent layer 119 is formed in such a way that materials each exhibiting red (R), green (G), and blue (B) color emission are formed selectively by vapor deposition with the use of respective deposition masks or by ink-jetting. Specifically, CuPc or PEDOT is employed as a HIL (hole injecting layer); α-NPD is employed as a HTL (hole transporting layer); BCP or Alq₃ is employed as an ETL (electron transporting layer); BCP:Li or CaF₂ is employed as an EIL (electron injecting layer), respectively. For example, Alq₃ doped with dopant in accordance with the respective colors of R, G, and B (DCM and the like in case of R, DMQD and the like in case of G) may be employed as the EML.

Thereafter, the second electrode 120 of the light emitting element is covered with an insulating film made of a silicon nitride film etc. to prevent the electroluminescent layer 119 from being deteriorated by moisture and oxygen. The substrate is adhered to a counter substrate with a sealing agent. A space between the substrate and the counter substrate formed by adhering these substrates may be filled with an inert gas such as nitrogen or a material having light transmitting properties and high hygroscopic properties.

Accordingly, the semiconductor device comprising the thin film transistor formed above; more specifically, the display device including the light emitting elements typified by the organic light emitting element in each pixel can be manufactured according to the present embodiment mode. Furthermore, a thin film transistor formed according to the embodiment mode is applicable to a pixel portion and a driver circuit portion of a semiconductor display device such as an integrated circuit; more especially, a liquid crystal display device, a DMD™ (Digital Micromirror Device™), a PDP (Plasma Display Panel), an FED (Field Emission Display), and the like.

[Embodiment Mode 3]

Embodiment Mode 3 will describe a case of crystallizing an amorphous semiconductor film by doping a metal element thereinto so as to form a crystalline semiconductor film in the thin film transistor of the driver circuit portion as described in Embodiment Mode 2.

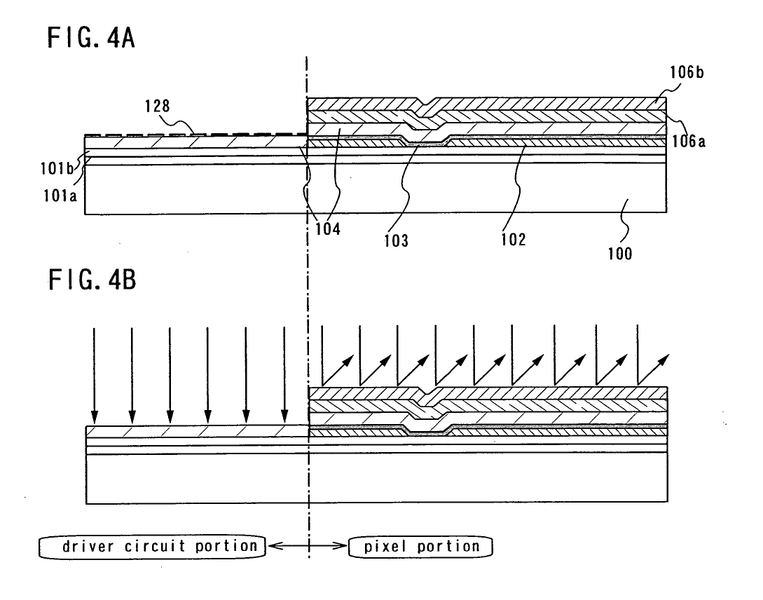

In FIG. 4A, the laminated films 106a and 106b are formed as a mask in a pixel portion in the same manner as FIG. 3A. While covering the pixel portion with the mask, a metal element is added over the surface of the substrate. The addition of the metal element indicates that the surface of the amorphous semiconductor film 104 is coated with the metal element so as to promote the crystallization of the amorphous semiconductor film. The amorphous semiconductor film can be crystallized at low temperatures by addition the metal element thereon.

For instance, Ni solution (including Ni aqueous solution and Ni acetate solution) is applied on the amorphous semiconductor film 104 by spin coating, dipping, and the like so as to form a film 128 containing Ni (note that, the film 128 including Ni sometimes cannot be observed because it is an extremely thin film). At this moment, in order to improve wettability of the surface of the amorphous semiconductor film 104 and to spread the Ni solution over the entire surface of the amorphous semiconductor film, an oxide film (not illustrated in the drawings) is desirably formed to a thickness of from 10 to 50 Å (i.e., from 1 to 5 nm) by performing UV light irradiation under an oxygen atmosphere; thermal oxidation; a treatment with ozone water or hydrogen peroxide including hydroxy radical, and the like. Furthermore, Ni ions may be injected into the amorphous semiconductor film by ion implantation; or the amorphous semiconductor film may be heated under a water vapor atmosphere containing Ni; or the amorphous semiconductor film may be sputtered with Ar plasma using an Ni material as a target. In the embodiment mode, an aqueous solution containing 10 ppm Ni acetate is applied to the amorphous semiconductor film 104 by spin coating.

Subsequently, the substrate is irradiated with the laser beam from a side of the top surface of the substrate as illustrated in FIG. 4B. As a result, the amorphous semiconductor film 104 in the driver circuit portion is crystallized to become a crystalline semiconductor film. At this moment, a heat treatment may be performed with the use of a heating furnace at 450 to 500° C. for 0.5 to 5.0 hours. Note that the heat treatment must be carried out so as not to crystallize the amorphous semiconductor film in the pixel portion where the entire surface thereof is covered with the mask.

The subsequent steps may refer to Embodiment Mode 2.

When the metal element is selectively added to the amorphous semiconductor film, the mask can be utilized according to the present embodiment mode.

As set forth above, the thin film transistor comprising the amorphous semiconductor film in the pixel portion and the crystalline semiconductor film in the driver circuit can be fabricated.

[Embodiment Mode 4]

In Embodiment Mode 4, a case of forming the masks as illustrated in FIG. 2A will be described.

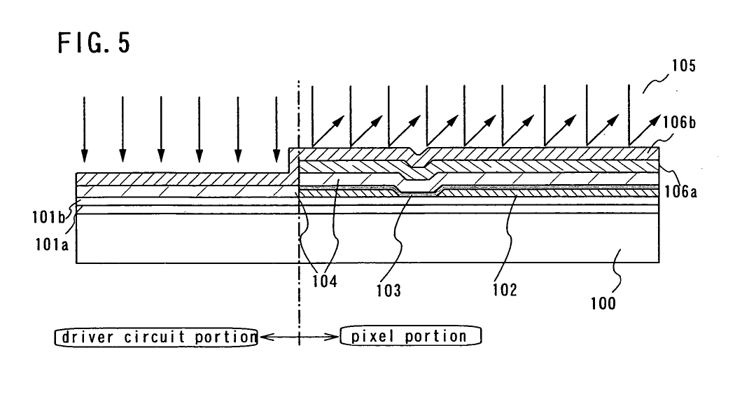

FIG. 5 shows a structure between the substrate and the amorphous semiconductor film 104, wherein the mask composed of the laminated films 106a and 106b is formed thereon in the pixel region as well as FIG. 3A. Further, a mask composed of a single-layered film 106b is formed in the driver circuit portion. Subsequently, laser beam is irradiated from a side of the top surface of the substrate.

By using these masks arranged in this manner, the amorphous semiconductor film 104 formed in the pixel portion remains in its amorphous state, whereas the amorphous semiconductor film 104 formed in the driver circuit portion is crystallized to become a crystalline semiconductor film. At this moment, the absorptance of the laser beam 105 can be especially enhanced by the single-layered film 106b formed in the driver circuit portion. As a result, the laser beam can be efficiently irradiated over the amorphous semiconductor film by using the masks as depicted in FIG. 5.

The subsequent steps may refer to Embodiment Mode 2.

The present embodiment mode can be implemented by being freely combined with foregoing Embodiment Mode 2 and Embodiment Mode 3.

[Embodiment Mode 5]

The present embodiment mode will describe steps for manufacturing a thin film transistor including a crystallization step performed by irradiating with a laser beam from a side of the back surface of the substrate with the use of masks, and steps for manufacturing a display device comprising a light emitting element typified by an organic light emitting element in each pixel. In the embodiment mode, a case where a thin film transistor formed in the pixel portion has a bottom-gate structure will be described.

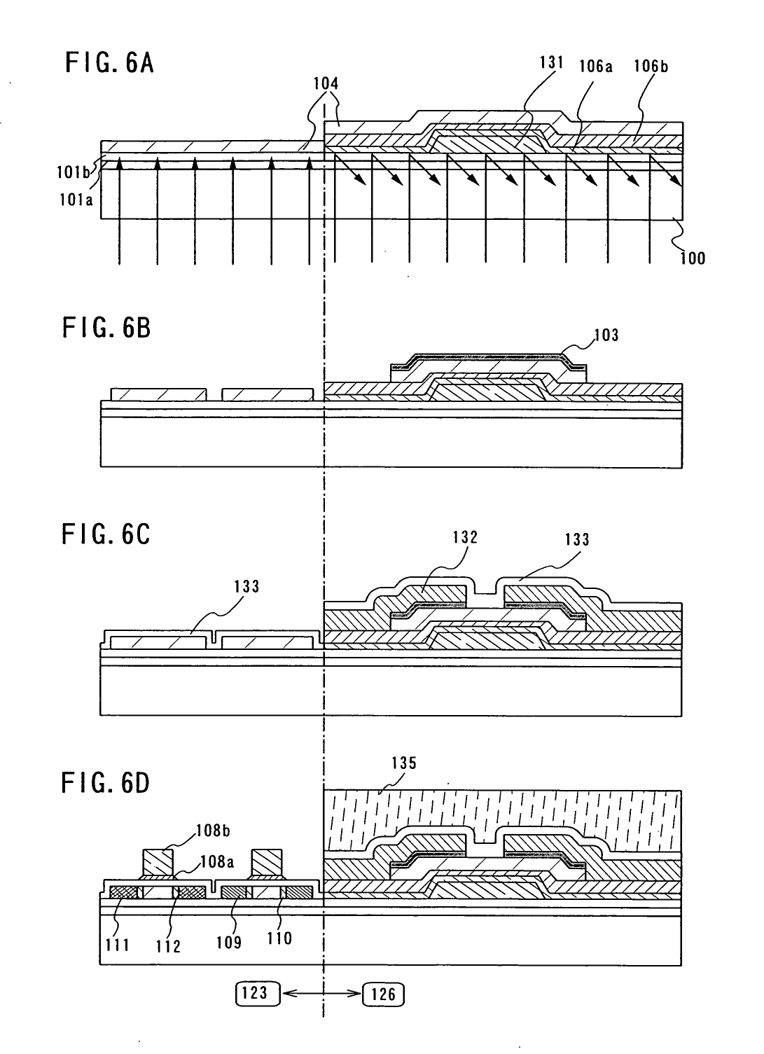

As shown in FIG. 6A, the base films 101 composed of the laminated film 101a and the laminated film 101b are formed over the substrate 100 having the insulated surface, as well as Embodiment Mode 2. In the pixel portion, a conductive film is formed over the base films 101 and patterned so as to serve as a gate electrode 131. Subsequently, the laminated films including the first material 106a and the second material 106b are formed as the mask to cover the gate electrode 131. The laminated films are preferable since they can also function as a gate insulating film in the pixel portion. Accordingly, a step for removing the laminated films can be eliminated.

Thereafter, the laser beam is irradiated from a side of the back surface of the substrate. At this moment, the base films 101 in the pixel portion are formed of a material or with a film thickness, which does not absorb the laser beam energy. Especially, it is preferable that a single-layered base film be formed in the driver circuit portion by using a material with a film thickness, which promotes absorption of the laser beam energy. For instance, a silicon nitride oxide (SiNO) film can be employed.

According to the above-mentioned structure, the amorphous semiconductor film 104 in the pixel portion is not irradiated with the laser beam because the laser beam is reflected by the laminated films 106a and 106b, and the gate electrode 131, and remains in its amorphous state. Meanwhile, the amorphous semiconductor film 104 in the driver circuit portion is crystallized by irradiation with the laser beam and becomes a crystalline semiconductor film.

As depicted in FIG. 6B, a semiconductor film 103 having an N-type conductivity is formed over the amorphous semiconductor film 104 in the pixel portion. At this moment, a resist mask and the like may be formed over the crystalline semiconductor film in the driver circuit portion. Then, the amorphous semiconductor film 104 in the pixel portion, the semiconductor film 103 having the N-type conductivity in the pixel portion, and the crystalline semiconductor film in the driver circuit portion are patterned.

As illustrated in FIG. 6C, a semiconductor film 132 having one conductivity type is formed over the semiconductor film 103 having the N-type conductivity in the pixel portion. Both semiconductor films are patterned to serve as a source electrode and a drain electrode. At this moment, the crystalline semiconductor film in the driver circuit portion may be covered with a resist mask and the like. Thereafter, an insulating film 133 is formed in the pixel portion and the driver circuit portion. The insulating film 133 formed in the driver circuit portion functions as a gate insulating film.

As depicted in FIG. 6D, a resist mask 135 etc. is formed over the pixel portion, whereas gate electrodes are formed over the crystalline semiconductor film provided in the driver circuit portion. The gate electrodes may be formed by laminating a first conductive film 108a and a second conductive film 108b in the same manner as Embodiment Mode 2. The first conductive film 108a and the second conductive film 108b are etched to serve as the gate electrodes as well as Embodiment Mode 2. By utilizing the gate electrodes as masks, an impurity region and a GOLD region are formed in a self-aligning manner. An n-channel impurity region 109 is formed by adding an impurity element such as boron (B), while a p-channel impurity region 111 is formed by adding an impurity element such as phosphorous (P).

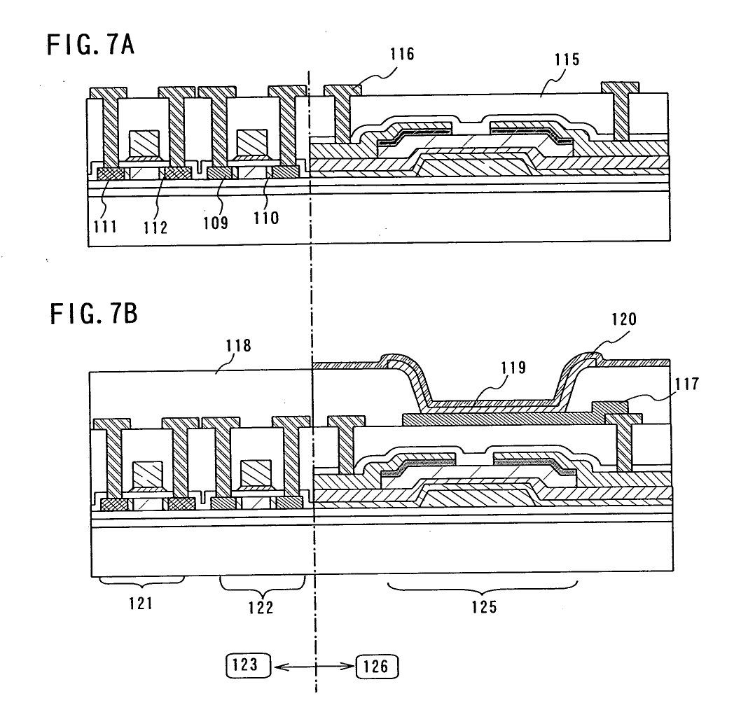

As illustrated in FIG. 7A, an interlayer insulating film 115 is formed and then each wiring 116 is formed in the same manner as Embodiment Mode 2. In the pixel portion 126, an amorphous semiconductor film, which is an n-channel TFT 125 having an amorphous silicon (a-Si) film in the present embodiment mode, is formed. Meanwhile, in the driver circuit portion 123, a crystalline semiconductor film, which includes an n-channel TFT 122 and p-channel TFT 121 each having a crystalline silicon (p-Si) film in the present embodiment mode, is formed. The n-channel TFT 125 formed in the pixel portion comprises a bottom-gate structure, while the n-channel TFT 122 and p-channel TFT 121 formed in the driver circuit portion comprise a top-gate structure.

Subsequently, an insulating film 118 is formed so as to cover each wiring 116, and then an opening is formed, as depicted in FIG. 7B. A first electrode 117 of the light emitting element is formed at the opening so as to be connected to a wiring, which is further connected to the drain electrode of the n-channel TFT in the pixel portion, i.e., a drain wiring. Then an electroluminescent layer 119 and a second electrode 120 are formed thereover.

Accordingly, the semiconductor device comprising the thin film transistor formed above; more specifically, the display device including the light emitting element typified by the organic light emitting element in each pixel in the present embodiment mode can be manufactured. Furthermore, a thin film transistor formed according to the embodiment mode is applicable to the pixel portion and the driver circuit portion of the semiconductor display device such as a integrated circuit; more especially, a liquid crystal display device, a DMD™ (Digital Micromirror Device™), a PDP (Plasma Display Panel), an FED (Field Emission Display), and the like.

The present embodiment mode can be implemented by being freely combined with the foregoing embodiment modes.

[Embodiment Mode 6]

The embodiment mode will show a case of crystallizing an amorphous semiconductor film by adding a metal element to form a crystalline semiconductor film in the thin film transistor used for the driver circuit portion as described in Embodiment Mode 2.

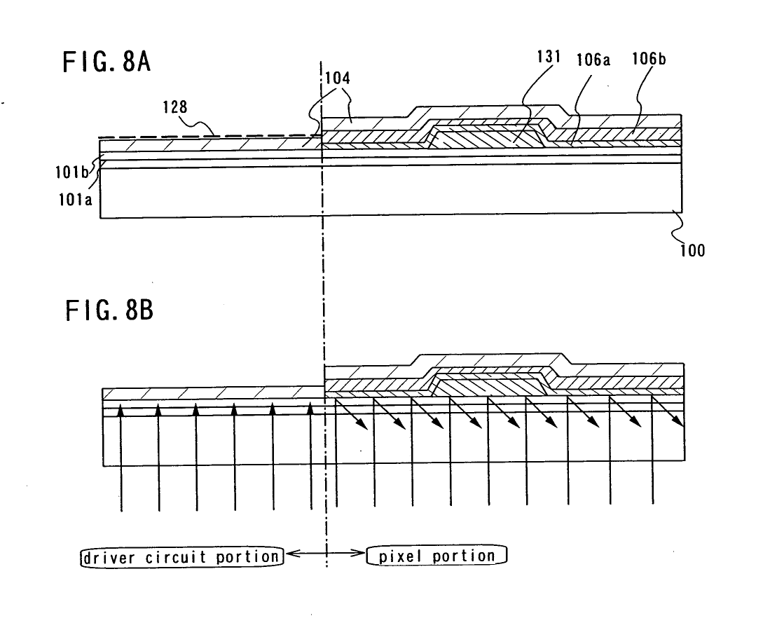

In FIG. 8A, the laminated films 106a and 106b are formed as the mask in the pixel portion as well as FIG. 6A. A metal element is doped into an amorphous semiconductor film while covering the pixel portion with the masks. The method for doping the metal element may refer to Embodiment Mode 3. For example, a film 128 containing Ni is formed. By adding the metal element, the amorphous semiconductor film can be crystallized at low temperatures.

Subsequently, laser beam is irradiated from a side of the back surface of the substrate as shown in FIG. 8B. As a result, the amorphous semiconductor film 104 in the driver circuit portion is crystallized to serve as a crystalline semiconductor film. At this moment, a heat treatment may be carried out by using an electric furnace at 450 to 500° C. for 0.5 to 5.0 hours. The amorphous semiconductor film 104 in the pixel portion is not crystallized since the surface thereof is covered with the mask.

The subsequent steps may refer to Embodiment Mode 5.

According to the present embodiment mode, the metal element can be selectively added to the semiconductor film with the use of the mask.

As set forth above, the thin film transistor having the amorphous semiconductor film is formed in the pixel portion, whereas the thin film transistor having the crystalline semiconductor film is formed in the driver circuit portion.

[Embodiment Mode 7]

The present embodiment mode will describe a case of irradiating with a laser beam from a side of a back surface of the substrate while covering the back surface of the substrate with a mask.

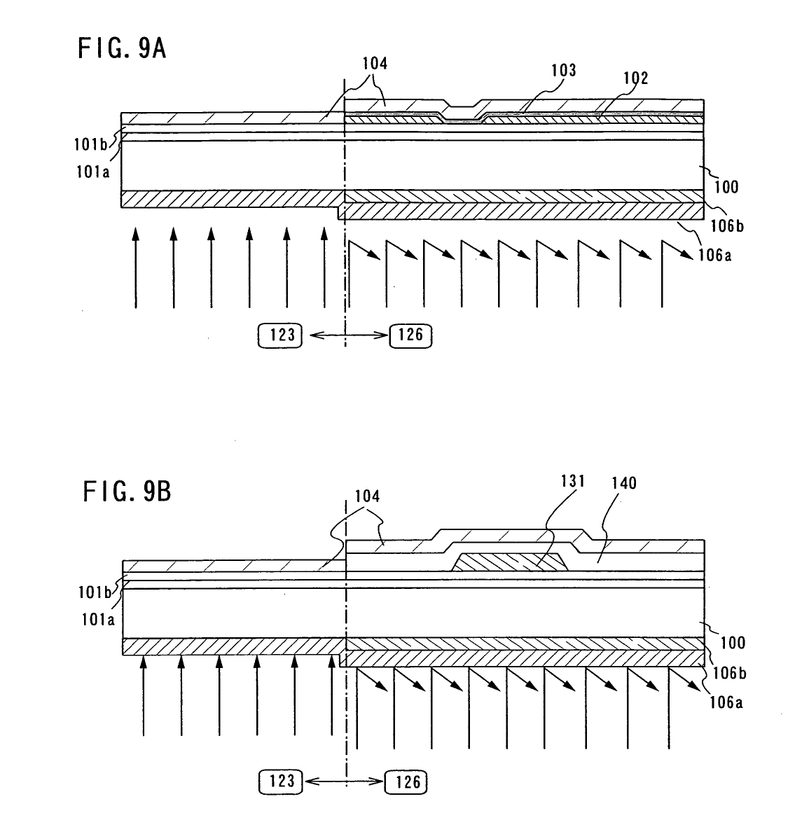

In FIG. 9A, a substrate is processed up to the step of forming the amorphous semiconductor film 104 in the same manner as FIG. 3A. Differing from FIG. 3A, however, masks are formed on the back surface of the substrate in FIG. 9A. Specifically, the masks are formed on the back surface of the substrate as follows: the laminated films 106a and 160b are formed in the pixel portion; and a single-layered film 106a is formed in the driver circuit portion.

Subsequently, the laser beam is irradiated from a side of the back surface of the substrate from under the substrate. At this moment, the amorphous semiconductor film 104 formed in the pixel portion remains in its amorphous state since the laminated films reflects the laser beam. The amorphous semiconductor film 104 formed in the driver circuit portion is crystallized by irradiating with the laser beam to become a crystalline semiconductor film. There is concern that the laser beam energy is attenuated by the substrate 100 in the driver circuit portion. However, the single-layered film 106a is formed on the back surface of the substrate in the driver circuit portion, and therefore, the energy absorptance of the laser beam can be enhanced.

In FIG. 9B, a substrate is also processed up to the step of forming the amorphous semiconductor film 104 in the same manner as FIG. 6A. Further, the insulating film 140, which functions as a gate insulating film, is formed as well as FIG. 6A. Differing from FIG. 6A, however, the insulating film 140 formed in the pixel portion is not necessary to have a function of absorbing the laser beam in FIG. 9B. Accordingly, the masks are formed on the back surface of the substrate. Specifically, the masks are formed on the back surface of the substrate as follows: the laminated films 106a and 106b are formed in the pixel portion; and the single-layered film 106a is formed in the driver circuit portion.

Thereafter, the laser beam is irradiated from a side of the back surface of the substrate. At this moment, the amorphous semiconductor film 104 formed in the pixel portion 126 remains in its amorphous state by the laminated film. Meanwhile, the amorphous semiconductor film 104 formed in the driver circuit portion 123 is crystallized by irradiating with the laser beam to become a crystalline semiconductor film. There is concern that the laser beam energy is attenuated by the substrate 100 in the driver circuit portion. However, the single-layered film 106a is formed on the back surface of the substrate in the driver circuit portion, and therefore, the energy absorptance of the laser beam can be improved.

As set forth above, the thin film transistor having the amorphous semiconductor film is formed in the pixel portion, whereas the thin film transistor having the crystalline semiconductor film is formed in the driver circuit portion.

[Embodiment Mode 8]

In the embodiment mode, a structure of a display device having a light emitting element in a pixel portion will be described.

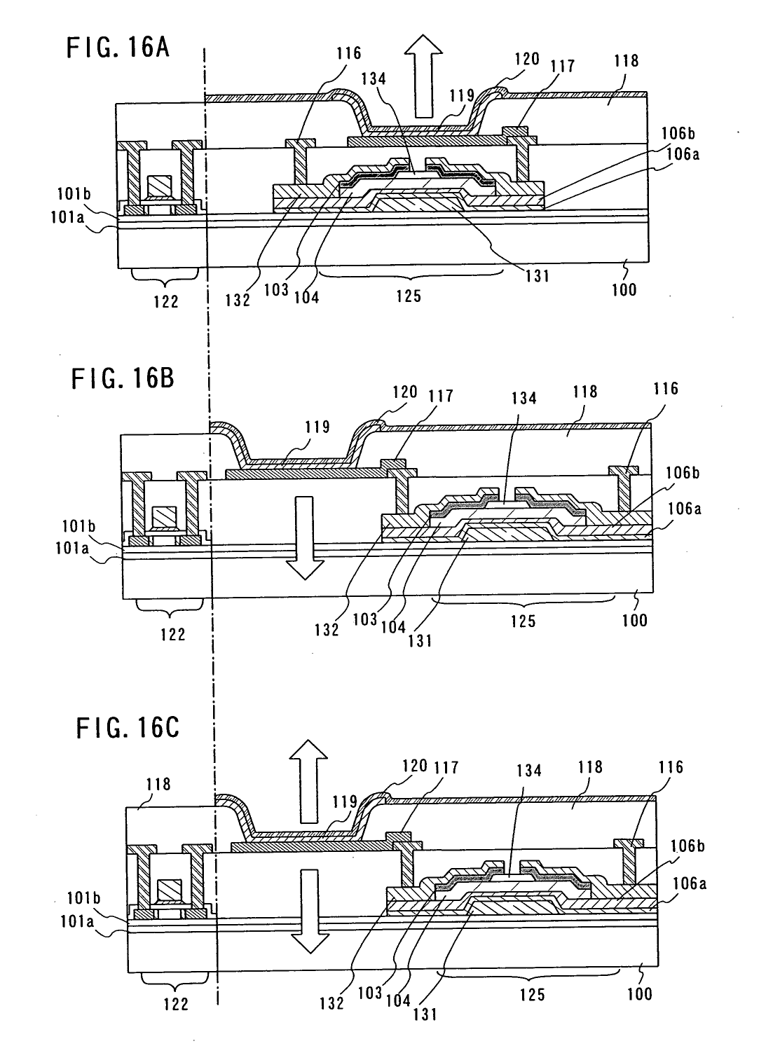

As depicted in FIG. 16A, an n-channel TFT 122 including a crystalline silicon film and an n-channel TFT 125 including an amorphous semiconductor film are formed over a substrate 100 having an insulated surface. Differing from the structure as illustrated in FIGS. 7A and 7B, the structure of the amorphous silicon film as illustrated in FIG. 16A has a channel protective film. The other structure in the TFTs will not be further explained. With respect to the structure of the amorphous silicon film as depicted in FIG. 16A, a channel protective film 134 made from an insulating film is formed so as to cover a channel formation region of the amorphous silicon film 104. The channel protective film 134 is provided in order to prevent the channel formation region of the amorphous silicon film from being etched in the step for manufacturing a source wiring and drain wiring of the TFTs. The structure of forming the channel protective film is sometimes referred to as a bottom-gate structure of channel protection type.

Subsequently, a semiconductor film 103 having an N-type conductivity is formed so as to cover the channel protective film 134 and the amorphous silicon film 104. A semiconductor film 132 having one conductivity type is formed on the semiconductor film 103 having the N-type conductivity, and is patterned to function as a source electrode and a drain electrode. The semiconductor film 103 having the N-type conductivity is also patterned in the same manner as the semiconductor film 132 having one conductivity type.

An insulating film 118 is formed to cover a first electrode (which is an anode in the present embodiment mode) 117 of the light emitting element, wirings 116, and edges of the first electrode 117 of the light emitting element. An electroluminescent layer 119 is formed at an opening of the insulating film. A second electrode (which is a cathode in the present embodiment mode) 120 of the light emitting element is formed on the electroluminescent layer.

In the structure of the display device as depicted in FIG. 16A, light generated in the electroluminescent layer 119 passes through the second electrode 120 (in the direction denoted by an arrow). Therefore, the first electrode 117 of the light emitting element is formed of a conductive material having high reflectiveness. The second electrode 120 of the light emitting element is formed of a conductive material having high light transmitting properties.

When the first electrode 117 and the second electrode 120 are formed of the above-mentioned materials, respectively, the first electrode 117 may serve as the cathode and the second electrode may serve as the anode while using a p-channel amorphous silicon film.

When the amorphous semiconductor film is used for the pixel portion, the channel formation region can be necessary to be designed largely from the viewpoint of electric current characteristics of the TFTs. In such case, a structure in which light generated in the electroluminescent layer 119 passes through the second electrode 120 is preferable as illustrated in FIG. 16A.

The structure of a display device as illustrated in FIG. 16B differs from the structure of FIG. 16A only in terms of the direction of light emitting from the electroluminescent layer, wherein light is emitted through the substrate 100. The other structure of the display device is same as that of FIG. 16A, and will not be further explained. According to the structure, the first electrode 117 is formed of a conductive material having high light transmitting properties, and the second electrode 120 is formed of a conductive material having high reflectiveness.

As illustrated in FIGS. 16A and 16B, light generated in the electroluminescent layer can be efficiently utilized by using the conductive film having high reflectiveness for the electrode of the light emitting element provided at the side from which light is not emitted.

The structure of a display device as illustrated in FIG. 16C differs from the structure of FIG. 16A only in terms of the direction of light emitting from the electroluminescent layer, wherein light passes through the substrate 100 and the second electrode 120. The other structure of the display device is same as that of FIG. 16A, and will not be further explained. According to the structure, the first electrode 117 and the second electrode 120 of the display device are made of a conductive material having high light transmitting properties.

In order to obtain the conductive material having high light transmitting properties, a conductive film having no light transmitting properties may be formed thinly so as to have the light transmitting properties, and another conductive film having the light transmitting properties may be laminated thereon.

As set forth above, the display device including the thin film transistor, which comprises the amorphous semiconductor film formed in the pixel portion, and another thin film transistor, which comprises the crystalline semiconductor film formed in the driver circuit portion, can be fabricated.

[Embodiment Mode 9]

In the embodiment mode, a method of manufacturing a plurality of panels from one substrate will be described.

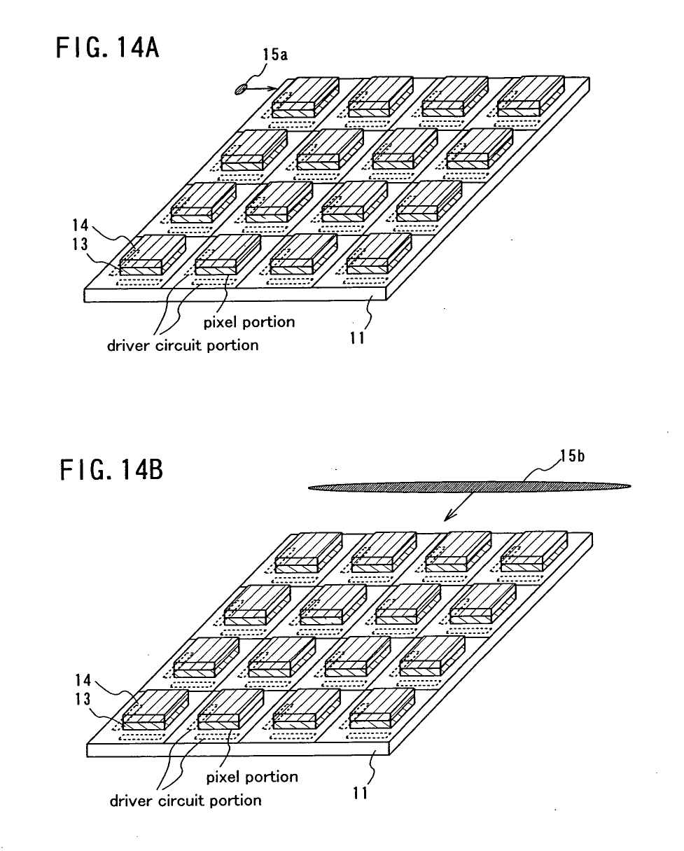

When sixteen panels are manufactured from one substrate as illustrated in FIG. 14A, for example, sixteen masks each of which is composed of a first material 13 and a second material 14 are formed in respective regions to be formed with pixel portions of an amorphous semiconductor film 11, respectively. The substrate is scanned with CW laser beam 15a in one direction of the substrate. By scanning the CW laser beam 15a back and forth, the entire surface of the amorphous semiconductor film 11 is irradiated with the laser beam. However, the CW laser beam is not high power under existing conditions; and therefore, the size of the laser beam processed into a linear shape becomes very small.

Alternatively, pulsed laser beam 15b can be used for scanning the substrate as illustrated in FIG. 14B. Since the pulsed laser beam has high power under existing conditions, the size of the pulsed laser beam processed into a linear shape can be made as large as about 30 cm in a longitudinal direction. Therefore, the entire surface of the amorphous semiconductor film 11 can be scanned with the pulsed laser beam by scanning once. Further, the direction of scanning the pulsed laser beam may be varied in each driver circuit portion. With respect to FIG. 14B, for example, the amorphous semiconductor film is scanned by changing the direction of irradiation with the pulsed laser beam 15b so as to much a major axis of each driver circuit portion with a major axis of the pulsed laser beam 15b.

Of course, a mask for reducing the reflectance of the laser beam 15a or 15b may be additionally formed in each driver circuit portion in FIGS. 14A and 14B.

According to the foregoing laser irradiation, each pixel portion covered with the masks remains in the amorphous state, while each driver circuit portion not covered with the masks is crystallized to become crystalline semiconductor films. Although the function of the masks, which is one feature of the present invention, has been emphasized in FIGS. 14A and 14B, the specific size of the masks may refer to the foregoing embodiment modes.

Subsequently, the sixteen panels are cut off from the substrate as illustrated in FIGS. 14A and 14B, thereby achieving a plurality of modules in which an integrated circuit (IC) including a controller, a power source circuit, an interface (I/F) portion and the like formed on a printed substrate is mounted on each panel via an FPC.

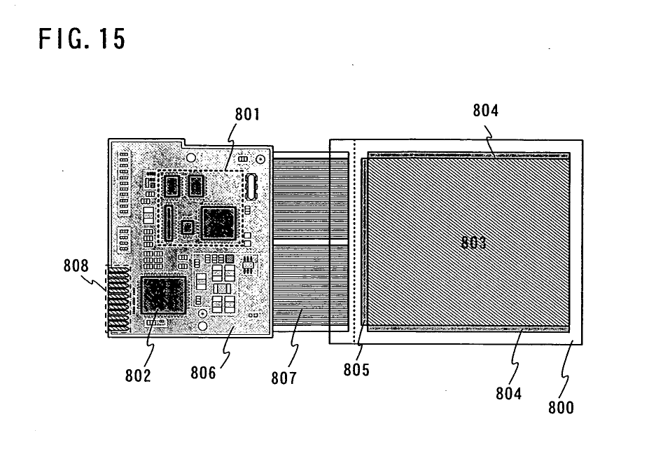

FIG. 15 shows an external view of a module in which a controller 801, and a power source circuit 802 are mounted on a panel 800. The panel 800 is provided with a pixel portion 803 in which a light emitting element or a liquid crystal element is provided in each pixel; a scanning line driver circuit 804 for selecting pixels of the pixel portion 803; and a signal line driver circuit 805 for supplying video signals to the selected pixels. The scanning line driver circuit 804 and the signal line driver circuit 805 correspond to a driver circuit portion. Semiconductor elements of the pixel portion 803 comprise an amorphous characteristic, whereas semiconductor elements of the scanning line driver circuit 804 and the signal line driver circuit 805 comprise a crystalline characteristic.

The scanning line driver circuit 804 and the signal line driver circuit 805 are not necessary to be formed on the same substrate. For example, only the scanning line driver circuit 804 may be formed over the substrate, and the signal line driver circuit 805 may be formed of an IC chip to be mounted on a panel. That is, according to the invention, the semiconductor elements of the pixel portion 803 comprise the amorphous characteristic, and the semiconductor elements of the driver circuit portion formed over the same substrate as the pixel portion comprise the crystalline characteristic.

Further, the controller 801 and the power source circuit 802 are formed over the printed substrate 806, wherein each signal and power source voltages output from the controller 801 and the power source circuit 802 are supplied to the pixel portion 803, the scanning line driver circuit 804, and the signal line driver circuit 805 of the panel 800 via the FPC 807.

The power source voltages and each signal are supplied to the printed substrate 806 via an interface (I/F) portion 808 in which a plurality of input terminals is arranged.

Although the printed substrate 806 is mounted on the panel 800 with use of the FPC in the present embodiment mode, the present invention is not particularly limited to the structure. Alternatively, the controller 801 and the power source circuit 802 may be mounted on the panel 800 directly by using a COG (chip on glass) technology.

Further, noise is sometimes generated in the power source voltages and each signal or the rising of each signal is sometimes delayed due to capacity generated between each wiring and resistance of each wiring in the printed substrate 806. Therefore, it is preferable that several kinds of elements such as a capacitor, and a buffer be formed over the printed substrate 806 to prevent the noise in the power source voltages and each signal, or the delay in rising of each signal.

As set forth above, the module having the amorphous semiconductor film and the crystalline semiconductor film can be formed.

[Embodiment Mode 10]

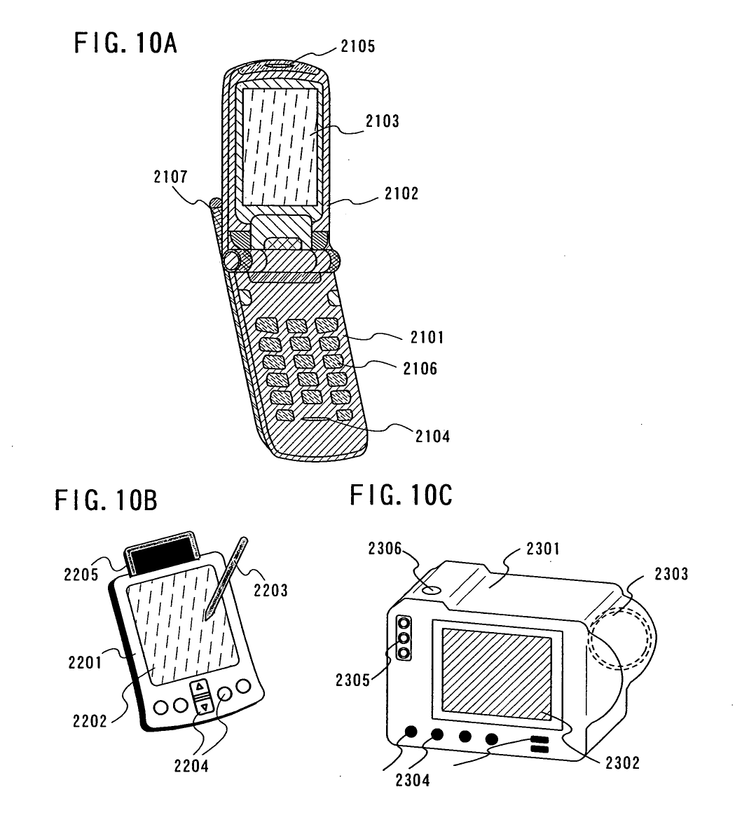

Examples of electronic appliances manufactured by utilizing the present invention include: a digital camera; an audio reproducing device such as a car audio component; a laptop computer; a game machine; a portable information terminal (such as a cellular phone, and a portable game machine); an image reproducing device provided with a recording medium such as a domestic gate machine, etc. Practical examples thereof are shown in FIGS. 10A to 10C.

FIG. 10A shows a cellular phone among portable terminals, including a main body 2101; a casing 2102; a display portion 2103; an audio input unit 2104; an audio output unit 2105; operation keys 2106; an antenna 2107, and the like. The display portion 2103 is provided with a module having a pixel portion and a driver circuit portion. The pixel portion comprises a light emitting element or a liquid crystal element, and TFTs including a semiconductor film, which remains in an amorphous state due to a mask. A dual emission panel, which emits light upwardly and downwardly, may be utilized for the pixel portion including a light emitting element. The driver circuit portion comprises a TFT including a crystalline semiconductor film, which is selectively crystallized. A plurality of panels for the display portion 2103 is mass-produced from one substrate as described in the foregoing embodiment mode, and hence, costs for manufacturing the cellular phone can be reduced.

FIG. 10B shows a mobile computer, including a main body 2201; a display portion 2202; a stylus 2203; operation keys 2204; an external interface 2205, and the like. The display portion 2203 is provided with a module having a pixel portion and a driver circuit portion. The pixel portion comprises a light emitting element or a liquid crystal element, and TFTs including a semiconductor film, which remains in an amorphous state due to a mask. The driver circuit portion comprises a TFT including a crystalline semiconductor film, which is selectively crystallized. A plurality of panels for the display portion 2202 is mass-produced from one substrate as described in the foregoing embodiment mode, thereby reducing costs for manufacturing the mobile computer.

FIG. 10C shows a digital still camera, including a main body 2301; a display portion 2302; an image receiving portion 2303; operation keys 2304; an external connection port 2305; a power switch 2306, and the like. The display portion 2302 is provided with a module having a pixel portion and a driver circuit portion. The pixel portion comprises a light emitting element or a liquid crystal element, and TFTs including a semiconductor film, which remains in an amorphous state due to a mask. The driver circuit portion comprises a TFT including a crystalline semiconductor film, which is selectively crystallized. A plurality of panels for the display portion 2302 is mass-produced from one substrate as described in the foregoing embodiment mode, thereby reducing costs for manufacturing the digital still camera.

Examples for the other electronic appliances include a display device; a laptop computer; an image reproducing device equipped with a recording medium (for example, a DVD player); a goggle type display; a video camera; and the like. With respect to these electronic appliances, a pixel portion thereof can comprise a light emitting element or a liquid crystal element, and TFTs including a semiconductor film, which remains in an amorphous state since the semiconductor film is covered with a mask. The driver circuit portion for these appliances can comprise TFTs including a crystalline semiconductor film, which is selectively crystallized.

When an amorphous semiconductor film is used for a thin film transistor of a pixel portion, the variation in adjacent thin film transistors can be reduced as compared with the case of using a polycrystalline semiconductor film. Furthermore, the variation in electric characteristics; especially, the variation in a threshold voltage (Vth) of the thin film transistor including the amorphous semiconductor film can be reduced. As a result, nonuniform display of the display device is reduced to enhance display quality.

By forming a plurality of panels for a display portion of various electric appliances from one substrate according to the foregoing embodiment mode, manufacturing costs for the electric appliances can be reduced.

The present embodiment mode can be implemented by being freely combined with the above-described embodiment modes.

[Embodiment 1]

In order to examine the crystallinity of semiconductor films in the case of forming a mask composed of laminated films and in the case of forming no mask, simulation of optical properties is carried out according to the following conditions of structure a and structure b (each film thickness is described in parentheses). Calculated results in the light transmittances, reflectances, and absorptances will be described as follows.

Structure a (with a mask): a substrate (#1737: product of Corning Incorporated)/a CVD-SiNO film (50 nm)/a CVD-SiON film (100 nm)/an amorphous silicon (a-Si) film (54 nm)/a SiON film (45 nm)/and a SiNO film (40 nm).

Structure b (with no mask): a substrate (#1737: product of Corning Incorporated)/a SiNO film (50 nm)/a SiON film (100 nm)/and an a-Si film (54 nm).

Note that, the SiNO films and SiON films manufactured by CVD are referred to as the CVD-SiNO films and CVD-SiON films, respectively.

The n value (refractive index) and k value (extinction coefficient) are referred to Table 1. In Table 1, SP—SiN indicates a SiN film formed by sputtering wherein silicon used as a target is deposited under a nitrogen atmosphere. Further, AQ in Table 1 indicates a structure including a substrate (#1737: product of Corning Incorporated); a CVD-SiNO film (50 nm); and a CVD-SiON film (100 nm), which serve as base films.

TABLE 1

| | n value | k value |
|---|---|---|
| a-Si | 3.53 | 3.3 |
| CVD-SiNO | 1.89 | 0.0022 |
| CVD-SiON | 1.51 | 0.0102 |
| SP-SiN | 2.2 | 0.0126 |
| AQ | 1.5 | 0 |

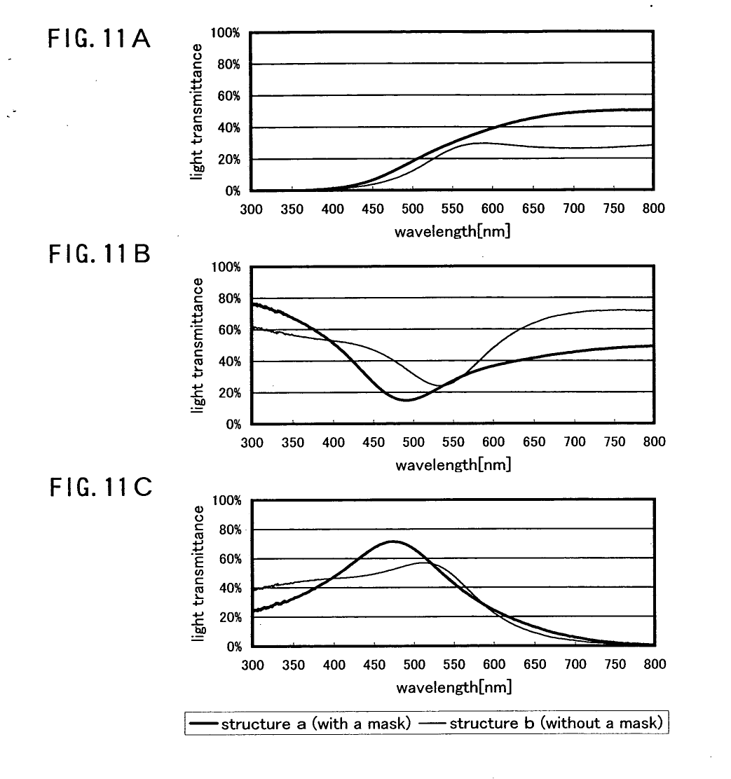

FIGS. 11A to 11C are graphs showing calculated light transmittances, reflectances, and absorptances with respect to the structure a and structure b, respectively in a wavelength from 300 to 800 nm. As compared with the structure b, when the laminated films having the predetermined film thicknesses such as the SiON film (45 nm) and the SiNO film (40 nm) are used as the mask in the structure a, the light transmittances, reflectances, and absorptances are fluctuated much more widely, respectively. Accordingly, each film thickness of the SiON film and SiNO film, which will serve as the mask, may be determined with reference to FIG. 11B so as to enhance the reflectance against the wavelength of laser beam to be irradiated.

According to the graph showing the absorptances in FIG. 11C, the structure b has wavelength regions having higher absorptances than those of the structure a. Accordingly, a region for increasing the reflectance and a region for increasing the absorptance can be formed of a same mask material, as described in FIGS. 2A and 2B.

On the other hand, Table 2 shows actual measurements obtained by measuring the optical properties in the case of excimer laser (308 nm in wavelength) with the use of a spectrophotometer, while Table 3 shows simulation values of the optical properties.

TABLE 2

| | light | | | absorption |
|---|---|---|---|---|
| structure | transmittance | reflectance | absorptance | ratio |
| structure a (with a | 0% | 76% | 24% | 0.61 |
| mask) | | | | |
| structure b | 0% | 61% | 39% | 1 |
| (without a mask) | | | | |

TABLE 3

| | light | | | absorption |
|---|---|---|---|---|
| structure | transmittance | reflectance | absorptance | ratio |
| structure a (with a | 0% | 68% | 32% | 0.71 |
| mask) | | | | |
| structure b | 0% | 55% | 45% | 1 |
| (without a | | | | |
| mask) | | | | |

The actual measurements are slightly different from the simulation values. However, the reflectance against the 308-nm laser wavelength of the structure a is increased as compared with that of the structure b. Therefore, it is revealed that the structure a functions as the mask. According to the energy absorptance (simply denoted as the absorptance in each table), which indicates the ratio of energy absorbed in a silicon film among total energy of laser beam irradiating the substrate, the energy absorptance of the structure a is smaller than that of the structure b.

Specifically, the energy absorption ratio (simply denoted as the absorption ratio in each table), which indicates the ratio of the energy absorptance of the structure a to the energy absorptance of the structure b, becomes 24%/39%=0.61 in the actual measurements. Meanwhile, the energy absorption ratio becomes 32%/45%=0.71 in the simulation values. As a result, it is revealed that structure a absorbs smaller amount of laser beam energy than the structure b.

[Embodiment 2]

In the present embodiment, in order to examine the structure of the laminated films used as a mask, simulation of optical properties is carried out by changing the film thicknesses of the SiON film and SiNO film in the following structure c and structure d (each film thickness is described in parentheses). Calculated results of each reflectance will be described as follows. As a laser beam, an excimer laser of 308 nm in wavelength is employed. The n value (refractive index) and k value (extinction coefficient) denoted in Table 1 are used.

Structure c: AQ/an a-Si film (54 nm)/a SiON film (0 to 200 nm)/a SiNO film (0 to 200 nm).

Structure d: AQ/an a-Si film (54 nm)/a SiNO film (0 to 200 nm)/a SiON film (0 to 200 nm).

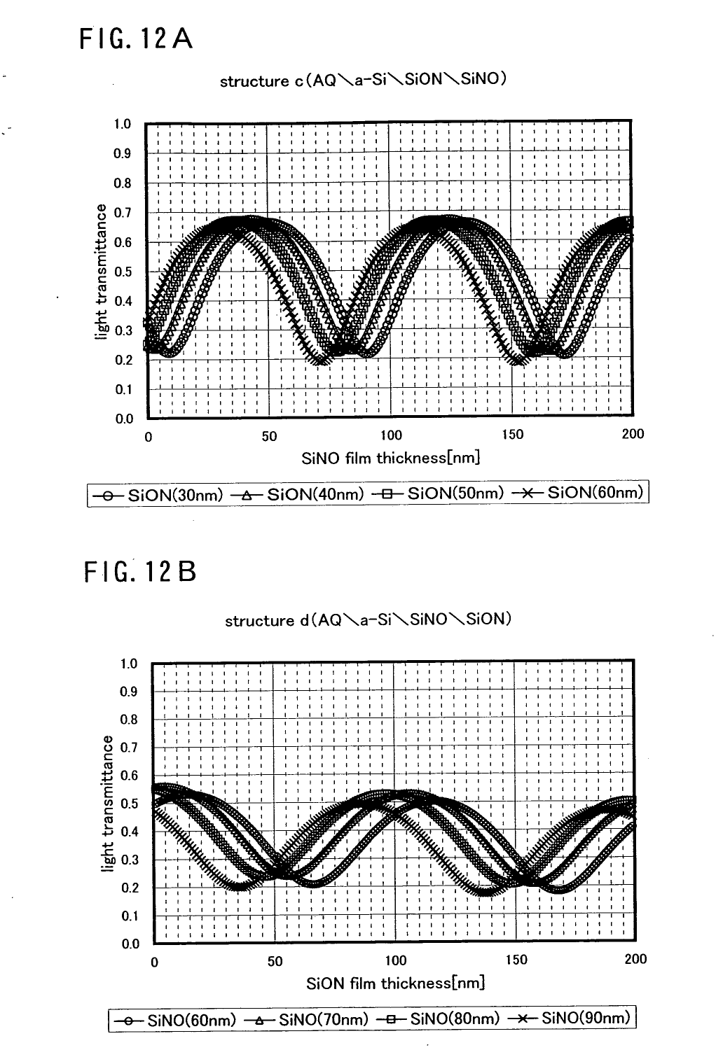

FIGS. 12A and 12B show results of simulation of the optical properties in the case where each film thickness of the SiON film and SiNO film is changed in the range of from 0 to 200 nm in the structure c and structure d, respectively. In the structure c, the reflectances are obtained in the case where the film thicknesses of the SiON film are set to 30 nm, 40 nm, 50 nm, and 60 nm, respectively; while the film thicknesses of the SiNO film is changed in the range of from 0 to 200 nm, respectively. Obtained results of the reflectances are shown in FIG. 12A. Meanwhile, in the structure d, the reflectances are obtained in the case where the film thicknesses of the SiNO film are set to 60 nm, 70 nm, 80 nm, and 90 nm, respectively; while the film thicknesses of the SiON film are changed in the range of from 0 to 200 nm. Obtained results of the reflectances are illustrated in FIG. 12B.

According to FIG. 12A, it is understood that the 68% maximum reflectance is obtained under the condition where the SiON film is 44 nm in thickness and the SiNO film is 40 nm in thickness in the structure c. On the other hand, according to FIG. 12B, an advantageous effect of increasing reflectance is not obtained in the structure d. Even where the SiON film is 0 nm in thickness and the SiNO film is 74 nm in thickness, only 56% of reflectance, which is almost equivalent to the state with no masks, is obtained.

Further, information about an antireflection film can be obtained according to the simulation results. In the case of the structure including the AQ, the a-Si film, and the SiNO film laminated in order, the reflectance is reduced to 11% by using the 34-nm-thick SiNO film. Also, in the case of the structure including the AQ, the a-Si film, and the SiON film laminated in order, the reflectance becomes 24% by using the 45-nm-thich SiON film.

Table 4 shows calculated values of energy reflectance in each interface.

TABLE 4

| structure | reflectance in each interface |
|---|---|
| CVD-SiON/air | 4.10% |
| CVD-SiNO/air | 8.80% |
| SP-SiN/air | 14.00% |
| SiNO | 1.00% |
| CVD-SiON/SP-SiN | 3.50% |
| CVD-SiNO/SP-SiN | 0.80% |
| a-Si/CVD-SiON | 16.10% |
| a-Si/CVD-SiNO | 9.90% |
| a-Si/SP-SiN | 5.40% |

According to the calculated values of Table 4, it is determined that the structure c provides a maximum reflectance. When the CVD-SiON film is formed on the a-Si film, this laminated structure can exhibits higher reflectance as compared with the case of forming the CVD-SiNO film or the Sp-SiN film on the a-Si film. Therefore, in the case of forming a mask only by CVD, a structure composed by laminating the 54-nm-thick a-Si film; the 51-nm-thick SiON film; and the 41.8-nm-thick SiNO film in order can exhibit maximum reflectance.

Furthermore, it is expected that a structure composed by laminating the AQ; the a-Si film; the CVD-SiON film; and a SP—SiN film, in which a SiN film formed by sputtering is used for a top layer, exhibits higher reflectance than the structure including the AQ; the a-Si film; the CVD-SiON; and the CVD-SiNO film. This is because the reflectance between the SP—SiN film and atmospheric air is a highest value. Therefore, when the mask is formed without limitation to the formation method, a structure composed by laminating the 54-nm-thick a-Si film, the 51-nm-thick SiON film, and the 35-nm-thick SP—SiN film can exhibit the maximum reflectance.

[Embodiment 3]

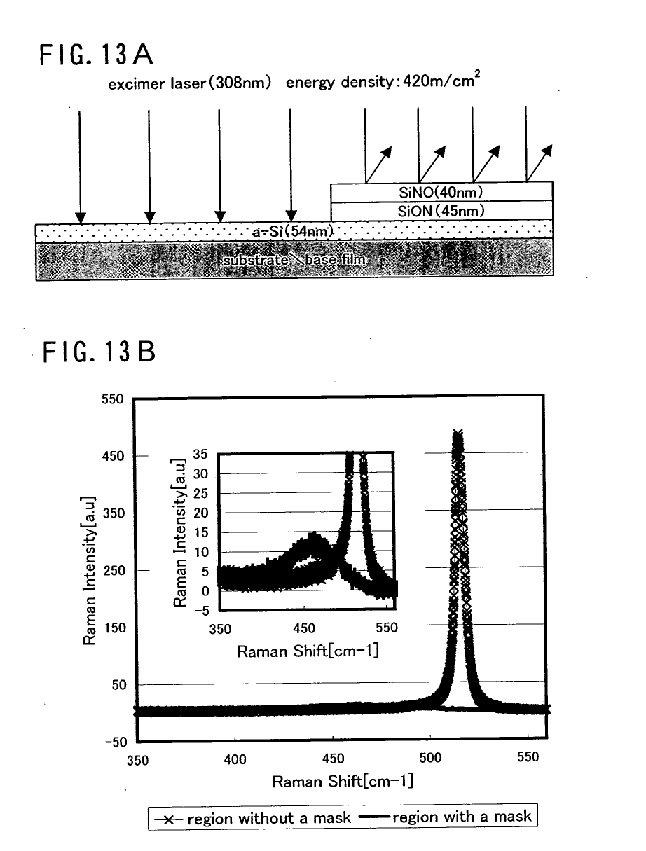

FIG. 13B shows the results of Raman spectrum in the case of irradiating with an excimer laser (308 nm in wavelength) with respect to a structure illustrated in FIG. 13A.

FIG. 13A shows a structure in which a base film is formed on a substrate, and a 45-nm-thick amorphous silicon (a-Si) film is formed thereon by CVD. A SiON film (45 nm in thickness) and a SiNO film (40 nm in thickness) are partly laminated on the amorphous silicon film as a mask. The mask including the above-mentioned structure is formed in accordance with the condition of exhibiting the maximum reflectance in the structure c in Embodiment 2, wherein the 44-nm-thick SiON film and the 40-nm-thick SiNO film are laminated in order.

The results of Raman spectrum in which a sample having the above-described structure is irradiated with the excimer laser (308 nm in wavelength) at an energy density of 420 mJ/cm² is shown in FIG. 13B.

According to FIG. 13B, even if the sample is irradiated with the excimer laser at the energy density of 420 mJ/cm², the Raman peak of a crystalline silicon film is not occurred in a region having no masks (which corresponds to the first region in the foregoing embodiment modes), and the Raman peak of the amorphous silicon film is kept as it is. It is considered that since the laser beam is reflected by the laminated films of the SiON film (45 nm in thickness) and the SiNO film (40 nm in thickness) partly formed as a mask, the temperature of the amorphous silicon film underneath the mask is not increased to a threshold value or more for crystallization of the silicon film, and therefore the amorphous silicon film remains in its amorphous sate.

In addition, when the energy density of the excimer laser is increased to 450 mJ/cm², the Raman peak of a polycrystalline silicon film can be observed even in the case of the region covered with the mask. When the energy density is increased to 450 mJ/cm² or more, it is preferable that the reflectance be increased by further laminating the same structure over the above-mentioned structure.

The present invention has been fully described by way of embodiment modes and embodiments with reference to the accompanying drawings. As has been easily understood by the person skilled in the art, the present invention can be embodied in several forms, and the embodiment modes and its details can be changed and modified without departing from the purpose and scope of the present invention. Accordingly, interpretation of the present invention should not be limited to descriptions mentioned in the foregoing embodiment modes and embodiments. Note that in the structures according to the present invention described above, portions identical to each other or portions having a similar function are commonly denoted by same reference numerals in the accompanying drawings such that additional descriptions are omitted.

1. A method of manufacturing a semiconductor device comprising:
forming an amorphous semiconductor film in a first region and a second region;
forming laminated films as a mask in the first region;
forming a crystalline semiconductor film by crystallizing the amorphous semiconductor film in the second region by irradiating the amorphous semiconductor film with a laser beam, wherein the laser beam is reflected by the mask in the first region;
forming a first thin film transistor including a portion of the amorphous semiconductor film in the first region; and
forming a second thin film transistor including a portion of the crystalline semiconductor film in the second region.

2. The method of manufacturing a semiconductor device according to claim 1, wherein the first region is a pixel portion and the second region is a driver circuit portion.

3. The method of manufacturing a semiconductor device according to claim 1, wherein when each of the laminated films is formed of a first film comprising a first material having the refractive index of n1 and a second film comprising a second material having the refractive index of n2 and the refractive indices satisfy n1<n2, the laminated films is formed by sequentially laminating the first film and the second film over the amorphous semiconductor film.

4. The method of manufacturing a semiconductor device according to claim 3, wherein the first material is silicon oxynitride and the second material is silicon nitride oxide or silicon nitride.

5. The method of manufacturing a semiconductor device according to claim 1, wherein when each of the laminated films is formed of a first film comprising a material having the refractive index of n1 and a second film comprising a material having the refractive index of n2, and the wavelength of the laser beam irradiated to the amorphous semiconductor film is λ, the film thickness of the first film satisfies (λ/4)×n1 and the film thickness of the second film satisfies (λ/4)×n2.

6. The method of manufacturing a semiconductor device according to claim 1, wherein each of the laminated films is formed of a first material and a second material each having 0.01 or less of the extinction coefficient with respect to the wavelength of irradiation with the laser beam.

7. The method of manufacturing a semiconductor device according to claim 1, wherein the first thin film transistor formed in the first region has a top-gate structure in which a gate electrode is formed over a channel formation region.

8. The method of manufacturing a semiconductor device according to claim 1, wherein the first thin film transistor formed in the first region has a bottom-gate structure in which a gate electrode is formed under a channel formation region.

9. The method of manufacturing a semiconductor device according to claim 1, wherein the laser beam is one or more of Ar laser; Kr laser; excimer laser; YAG laser; Y₂O₃ laser; YVO₄ laser; YLF laser; YAlO₃ laser; glass laser; ruby laser; alexandrite laser; Ti:sapphire laser; copper steam laser; and gold steam laser.

10. The method of manufacturing a semiconductor device according to claim 1, wherein a heat treatment is performed by selectively adding a metal element for promoting crystallization selected from one or more of Ni, Fe, Co, Pd, Pt, Cu, Au, Ag, In, and Sn into the amorphous semiconductor film prior to irradiation with the laser beam.

11. The method of manufacturing a semiconductor device according to claim 10, wherein the amorphous semiconductor film is selectively added with a solution containing the metal element for promoting crystallization by spin coating, dipping, ion implantation, or sputtering.

12. The method of manufacturing a semiconductor device according to claim 1, wherein the semiconductor device is used for a display device in which cathode of a light emitting element is formed so as to be contacted to any one of electrodes of the first thin film transistor formed in the first region, a light emitting layer is formed on the cathode, and an anode of the light emitting element is formed to cover the light emitting layer.

13. The method of manufacturing a semiconductor device according to claim 12, the display device is used for an electronic apparatus selected from the group consist of a digital still camera, a mobile computer, and a cellular phone.

14. A method of manufacturing a semiconductor device comprising:
forming an amorphous semiconductor film in a first region and a second region;
forming laminated films as a mask in the first region;
forming a crystalline semiconductor film by crystallizing the amorphous semiconductor film in the second region by irradiating the amorphous semiconductor film with a laser beam, wherein the laser beam is reflected by the mask in the first region;
forming a first n-channel thin film transistor including a portion of the amorphous semiconductor film in the first region; and
forming a second n-channel thin film transistor and a third p-channel thin film transistor including a portion of the crystalline semiconductor film in the second region.

15. The method of manufacturing a semiconductor device according to claim 14, wherein the first region is a pixel portion and the second region is a driver circuit portion.

16. The method of manufacturing a semiconductor device according to claim 14, wherein when each of the laminated films is formed of a first film comprising a first material having the refractive index of n1 and a second film comprising a second material having the refractive index of n2 and the refractive indices satisfy n1<n2, the laminated films is formed by sequentially laminating the first film and the second film over the amorphous semiconductor film.

17. The method of manufacturing a semiconductor device according to claim 16, wherein the first material is silicon oxynitride and the second material is silicon nitride oxide or silicon nitride.

18. The method of manufacturing a semiconductor device according to claim 14, wherein when each of the laminated films is formed of a first film comprising a material having the refractive index of n1 and a second film comprising a material having the refractive index of n2, and the wavelength of the laser beam irradiated to the amorphous semiconductor film is λ, the film thickness of the first film satisfies (λ/4)×n1 and the film thickness of the second film satisfies (λ/4)×n2.

19. The method of manufacturing a semiconductor device according to claim 14, wherein each of the laminated films is formed of a first material and a second material each having 0.01 or less of the extinction coefficient with respect to the wavelength of irradiation with the laser beam.

20. The method of manufacturing a semiconductor device according to claim 14, wherein the first thin film transistor formed in the first region has a top-gate structure in which a gate electrode is formed over a channel formation region.

21. The method of manufacturing a semiconductor device according to claim 14, wherein the first thin film transistor formed in the first region has a bottom-gate structure in which a gate electrode is formed under a channel formation region.

22. The method of manufacturing a semiconductor device according to claim 14, wherein the laser beam is one or more of Ar laser; Kr laser; excimer laser; YAG laser; Y₂O₃ laser; YVO₄ laser; YLF laser; YAlO₃ laser; glass laser; ruby laser; alexandrite laser; Ti:sapphire laser; copper steam laser; and gold steam laser.

23. The method of manufacturing a semiconductor device according to claim 14, wherein a heat treatment is performed by selectively adding a metal element for promoting crystallization selected from one or more of Ni, Fe, Co, Pd, Pt, Cu, Au, Ag, In, and Sn into the amorphous semiconductor film prior to irradiation with the laser beam.

24. The method of manufacturing a semiconductor device according to claim 23, wherein the amorphous semiconductor film is selectively added with a solution containing the metal element for promoting crystallization by spin coating, dipping, ion implantation, or sputtering.

25. The method of manufacturing a semiconductor device according to claim 14, wherein the semiconductor device is used for a display device in which cathode of a light emitting element is formed so as to be contacted to any one of electrodes of the first thin film transistor formed in the first region, a light emitting layer is formed on the cathode, and an anode of the light emitting element is formed to cover the light emitting layer.

26. The method of manufacturing a semiconductor device according to claim 25, the display device is used for an electronic apparatus selected from the group consist of a digital still camera, a mobile computer, and a cellular phone.

27. A method of manufacturing a semiconductor device comprising:
forming an amorphous semiconductor film in a first region and a second region;
forming laminated films as a mask in the first region and a single-layered film which is one of the plurality of laminated films in the second region;
forming a crystalline semiconductor film by crystallizing the amorphous semiconductor film in the second region by irradiating the amorphous semiconductor film with a laser beam, wherein the laser beam is reflected by the mask in the first region;
forming a first n-channel thin film transistor including a portion of the amorphous semiconductor film in the first region; and
forming a second n-channel thin film transistor and a third p-channel thin film transistor including a portion of the crystalline semiconductor film in the second region.

28. The method of manufacturing a semiconductor device according to claim 27, wherein the first region is a pixel portion and the second region is a driver circuit portion.

29. The method of manufacturing a semiconductor device according to claim 27, wherein when each of the laminated films is formed of a first film comprising a first material having the refractive index of n1 and a second film comprising a second material having the refractive index of n2 and the refractive indices satisfy n1<n2, the laminated films is formed by sequentially laminating the first film and the second film over the amorphous semiconductor film.

30. The method of manufacturing a semiconductor device according to claim 29, wherein the first material is silicon oxynitride and the second material is silicon nitride oxide or silicon nitride.

31. The method of manufacturing a semiconductor device according to claim 27, wherein when each of the laminated films is formed of a first film comprising a material having the refractive index of n1 and a second film comprising a material having the refractive index of n2, and the wavelength of the laser beam irradiated to the amorphous semiconductor film is λ, the film thickness of the first film satisfies (λ/4)×n1 and the film thickness of the second film satisfies (λ/4)×n2.

32. The method of manufacturing a semiconductor device according to claim 27, wherein each of the laminated films is formed of a first material and a second material each having 0.01 or less of the extinction coefficient with respect to the wavelength of irradiation with the laser beam.

33. The method of manufacturing a semiconductor device according to claim 27, wherein the first thin film transistor formed in the first region has a top-gate structure in which a gate electrode is formed over a channel formation region.

34. The method of manufacturing a semiconductor device according to claim 27, wherein the first thin film transistor formed in the first region has a bottom-gate structure in which a gate electrode is formed under a channel formation region.

35. The method of manufacturing a semiconductor device according to claim 27, wherein the laser beam is one or more of Ar laser; Kr laser; excimer laser; YAG laser; Y₂O₃ laser; YVO₄ laser; YLF laser; YAlO₃ laser; glass laser; ruby laser; alexandrite laser; Ti:sapphire laser; copper steam laser; and gold steam laser.

36. The method of manufacturing a semiconductor device according to claim 27, wherein a heat treatment is performed by selectively adding a metal element for promoting crystallization selected from one or more of Ni, Fe, Co, Pd, Pt, Cu, Au, Ag, In, and Sn into the amorphous semiconductor film prior to irradiation with the laser beam.

37. The method of manufacturing a semiconductor device according to claim 36, wherein the amorphous semiconductor film is selectively added with a solution containing the metal element for promoting crystallization by spin coating, dipping, ion implantation, or sputtering.

38. The method of manufacturing a semiconductor device according to claim 27, wherein the semiconductor device is used for a display device in which cathode of a light emitting element is formed so as to be contacted to any one of electrodes of the first thin film transistor formed in the first region, a light emitting layer is formed on the cathode, and an anode of the light emitting element is formed to cover the light emitting layer.

39. The method of manufacturing a semiconductor device according to claim 38, the display device is used for an electronic apparatus selected from the group consist of a digital still camera, a mobile computer, and a cellular phone.

40. A method of manufacturing a semiconductor device comprising:
forming an amorphous semiconductor film in a first region and a second region over a first surface of a substrate, wherein the first surface and a second surface of the substrate is opposite each other;
forming laminated films as a mask adjacent to the second surface of the substrate in the first region;
forming a crystalline semiconductor film by crystallizing the amorphous semiconductor film in the second region by irradiating the amorphous semiconductor film with a laser beam from a side of the second surface of the substrate, wherein the laser beam is reflected by the mask in the first region;
forming a first n-channel thin film transistor including a portion of the amorphous semiconductor film in the first region; and
forming a second n-channel thin film transistor and a third p-channel thin film transistor including a portion of the crystalline semiconductor film in the second region.

41. The method of manufacturing a semiconductor device according to claim 40, wherein the first region is a pixel portion and the second region is a driver circuit portion.

42. The method of manufacturing a semiconductor device according to claim 40, wherein when each of the laminated films is formed of a first film comprising a first material having the refractive index of n1 and a second film comprising a second material having the refractive index of n2 and the refractive indices satisfy n1<n2, the laminated films is formed by sequentially laminating the first film and the second film over the amorphous semiconductor film.

43. The method of manufacturing a semiconductor device according to claim 42, wherein the first material is silicon oxynitride and the second material is silicon nitride oxide or silicon nitride.

44. The method of manufacturing a semiconductor device according to claim 40, wherein when each of the laminated films is formed of a first film comprising a material having the refractive index of n1 and a second film comprising a material having the refractive index of n2, and the wavelength of the laser beam irradiated to the amorphous semiconductor film is λ, the film thickness of the first film satisfies (λ/4)×n1 and the film thickness of the second film satisfies (λ/4)×n2.

45. The method of manufacturing a semiconductor device according to claim 40, wherein each of the laminated films is formed of a first material and a second material each having 0.01 or less of the extinction coefficient with respect to the wavelength of irradiation with the laser beam.

46. The method of manufacturing a semiconductor device according to claim 40, wherein the first thin film transistor formed in the first region has a top-gate structure in which a gate electrode is formed over a channel formation region.

47. The method of manufacturing a semiconductor device according to claim 40, wherein the first thin film transistor formed in the first region has a bottom-gate structure in which a gate electrode is formed under a channel formation region.

48. The method of manufacturing a semiconductor device according to claim 40, wherein the laser beam is one or more of Ar laser; Kr laser; excimer laser; YAG laser; Y₂O₃ laser; YVO₄ laser; YLF laser; YAlO₃ laser; glass laser; ruby laser; alexandrite laser; Ti:sapphire laser; copper steam laser; and gold steam laser.

49. The method of manufacturing a semiconductor device according to claim 40, wherein a heat treatment is performed by selectively adding a metal element for promoting crystallization selected from one or more of Ni, Fe, Co, Pd, Pt, Cu, Au, Ag, In, and Sn into the amorphous semiconductor film prior to irradiation with the laser beam.

50. The method of manufacturing a semiconductor device according to claim 49, wherein the amorphous semiconductor film is selectively added with a solution containing the metal element for promoting crystallization by spin coating, dipping, ion implantation, or sputtering.

51. The method of manufacturing a semiconductor device according to claim 40, wherein the semiconductor device is used for a display device in which cathode of a light emitting element is formed so as to be contacted to any one of electrodes of the first thin film transistor formed in the first region, a light emitting layer is formed on the cathode, and an anode of the light emitting element is formed to cover the light emitting layer.

52. The method of manufacturing a semiconductor device according to claim 51, the display device is used for an electronic apparatus selected from the group consist of a digital still camera, a mobile computer, and a cellular phone.

53. A method of manufacturing a semiconductor device comprising:
forming an amorphous semiconductor film in a first region and a second region over a first surface of a substrate, wherein the first surface and a second surface of the substrate is opposite each other;
forming laminated films as a mask adjacent to the second surface of the substrate in the first region and a single-layered film which is one of the plurality of laminated films adjacent to the second surface of the substrate in the second region;
forming a crystalline semiconductor film by crystallizing the amorphous semiconductor film in the second region by irradiating the amorphous semiconductor film with a laser beam from a side of the second surface of the substrate, wherein the laser beam is reflected by the mask in the first region;
forming a first n-channel thin film transistor including a portion of the amorphous semiconductor film in the first region; and
forming a second n-channel thin film transistor and a third p-channel thin film transistor including a portion of the crystalline semiconductor film in the second region.

54. The method of manufacturing a semiconductor device according to claim 53, wherein the first region is a pixel portion and the second region is a driver circuit portion.

55. The method of manufacturing a semiconductor device according to claim 53, wherein when each of the laminated films is formed of a first film comprising a first material having the refractive index of n1 and a second film comprising a second material having the refractive index of n2 and the refractive indices satisfy n1<n2, the laminated films is formed by sequentially laminating the first film and the second film over the amorphous semiconductor film.

56. The method of manufacturing a semiconductor device according to claim 55, wherein the first material is silicon oxynitride and the second material is silicon nitride oxide or silicon nitride.

57. The method of manufacturing a semiconductor device according to claim 53, wherein when each of the laminated films is formed of a first film comprising a material having the refractive index of n1 and a second film comprising a material having the refractive index of n2, and the wavelength of the laser beam irradiated to the amorphous semiconductor film is λ, the film thickness of the first film satisfies (λ/4)×n1 and the film thickness of the second film satisfies (λ/4)×n2.

58. The method of manufacturing a semiconductor device according to claim 53, wherein each of the laminated films is formed of a first material and a second material each having 0.01 or less of the extinction coefficient with respect to the wavelength of irradiation with the laser beam.

59. The method of manufacturing a semiconductor device according to claim 53, wherein the first thin film transistor formed in the first region has a top-gate structure in which a gate electrode is formed over a channel formation region.

60. The method of manufacturing a semiconductor device according to claim 53, wherein the first thin film transistor formed in the first region has a bottom-gate structure in which a gate electrode is formed under a channel formation region.

61. The method of manufacturing a semiconductor device according to claim 53, wherein the laser beam is one or more of Ar laser; Kr laser; excimer laser; YAG laser; Y₂O₃ laser; YVO₄ laser; YLF laser; YAlO₃ laser; glass laser; ruby laser; alexandrite laser; Ti:sapphire laser; copper steam laser; and gold steam laser.

62. The method of manufacturing a semiconductor device according to claim 53, wherein a heat treatment is performed by selectively adding a metal element for promoting crystallization selected from one or more of Ni, Fe, Co, Pd, Pt, Cu, Au, Ag, In, and Sn into the amorphous semiconductor film prior to irradiation with the laser beam.

63. The method of manufacturing a semiconductor device according to claim 62, wherein the amorphous semiconductor film is selectively added with a solution containing the metal element for promoting crystallization by spin coating, dipping, ion implantation, or sputtering.

64. The method of manufacturing a semiconductor device according to claim 53, wherein the semiconductor device is used for a display device in which cathode of a light emitting element is formed so as to be contacted to any one of electrodes of the first thin film transistor formed in the first region, a light emitting layer is formed on the cathode, and an anode of the light emitting element is formed to cover the light emitting layer.

65. The method of manufacturing a semiconductor device according to claim 64, the display device is used for an electronic apparatus selected from the group consist of a digital still camera, a mobile computer, and a cellular phone.
